(19) United States
(12) Patent Application Publication
(10) Pub. No.: US 2025/0226220 A1
(43) Pub. Date: Jul. 10, 2025

(54) SEMICONDUCTOR DEVICE AND METHOD OF MANUFACTURING THE SAME

(71) Applicant: Samsung Electronics Co., Ltd., Suwon-si (KR)

(72) Inventors: TAE-HOI PARK, Suwon-si (KR); SOL JEONG, Suwon-si (KR); Jinseong GWAK, Suwon-si (KR); ILHWAN KIM, Suwon-si (KR)

(21) Appl. No.: 18/772,317

(22) Filed: Jul. 15, 2024

(30) Foreign Application Priority Data
Jan. 4, 2024 (KR) 10-2024-0001697

(51) Int. Cl. H01L 21/027; H01L 21/3213

(52) U.S. Cl. CPC H01L 21/0276; H01L 21/32139

(57) ABSTRACT

A method of manufacturing includes forming a first anti-reflection pattern on a substrate, forming a photoresist pattern on the first anti-reflection pattern, forming a first polymer pattern on the photoresist pattern, forming a copolymer layer on the first anti-reflection pattern and the first polymer pattern, and performing an annealing process on the copolymer layer, wherein the copolymer layer includes a first polymer and a second polymer different from the first polymer, and the first polymer pattern includes the first polymer.

### CROSS-REFERENCE TO RELATED APPLICATIONS

This U.S. non-provisional patent application claims priority under 35 U.S.C. § 119 to Korean Patent Application No.10-2024-0001697 filed on Jan. 4, 2024, in the Korean Intellectual Property Office, the entire contents of which are hereby incorporated by reference.

### BACKGROUND

The inventive concept relates to a semiconductor device and a method of manufacturing the same, and more particularly, relates to a semiconductor device including a field effect transistor and a method of manufacturing the same.

A semiconductor device may include an integrated circuit including metal-oxide-semiconductor field-effect transistors (MOSFET). To meet an increasing demand for a semiconductor device with a small pattern size and a reduced design rule, MOSFETs are being aggressively scaled down. The scale-down of MOSFETs may lead to deterioration in operational properties of semiconductor devices. A variety of studies are being conducted to overcome technical limitations associated with the scale-down of semiconductor devices and to realize semiconductor devices with high performance.

### SUMMARY

Some aspects of the inventive concept provide a semiconductor device with improved reliability and electrical characteristics.

Some aspects of the inventive concept provide a method of manufacturing a semiconductor device with improved reliability and electrical characteristics.

A method of manufacturing a semiconductor device according to some embodiments of the inventive concept includes forming a first anti-reflection pattern on a substrate, forming a photoresist pattern on the first anti-reflection pattern, forming a first polymer pattern on the photoresist pattern, forming a copolymer layer on the first anti-reflection pattern and the first polymer pattern, and performing an annealing process on the copolymer layer, wherein the copolymer layer includes a first polymer and a second polymer different from the first polymer, and the first polymer pattern includes the first polymer.

A method of manufacturing a semiconductor device according to some embodiments of the inventive concept includes forming an anti-reflection pattern and a photoresist layer sequentially stacked on a substrate, irradiating the photoresist layer with extreme ultraviolet light to form a photoresist pattern, forming a first polymer pattern on the photoresist pattern, forming a copolymer layer covering a first material region on the first polymer pattern and a second material region on the anti-reflection pattern, and performing an annealing process on the copolymer layer, wherein one of the first material region and the second material region is polar and the other is non-polar.

A method of manufacturing a semiconductor device according to some embodiments of the inventive concept includes forming transistors on a substrate and forming a first wiring layer on the transistor, wherein the forming of the first wiring layer, forming an interlayer insulating layer, a first anti-reflection pattern, and a photoresist pattern sequentially stacked on the transistor, forming a first polymer pattern on the photoresist pattern, forming a copolymer layer on the first anti-reflection pattern and the first polymer pattern, the copolymer layer including a first polymers and a second polymers different from each other, and phase-separating the copolymer layer, and the phase-separating of the copolymer layer includes aligning the first polymer in a vertical direction on the first polymer pattern.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a schematic diagram showing an EUV exposure apparatus according to embodiments of the inventive concept.

FIGS. 2 to 8 are cross-sectional views for explaining a photolithography process according to embodiments of the inventive concept.

FIGS. 9A to 9D are cross-sectional views for explaining a photolithography process according to another embodiment of the inventive concept.

FIG. 10 is a plan view for explaining a semiconductor device according to embodiments of the inventive concept.

FIGS. 11A to 11D are cross-sectional views taken in lines A-A′, B-B′, C-C′, and D-D′ of FIG. 10, respectively.

FIGS. 12A, 12B, 13A, 13B, 14A to 14C, 15A to 15D, 16A to 16C, and 17A to 17C are cross-sectional views for explaining a method of manufacturing a semiconductor device according to embodiments of the inventive concept.

FIGS. 18 to 25 are cross-sectional views for explaining the method of forming the semiconductor device of FIG. 11D.

### DETAILED DESCRIPTION

Hereinafter, to explain the inventive concept in detail, embodiments according to the inventive concept will be described with reference to the accompanying drawings.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. Other words used to describe the relationship between elements should be interpreted in a like fashion (e.g., “between” versus “directly between,” “adjacent” versus “directly adjacent,” etc.).

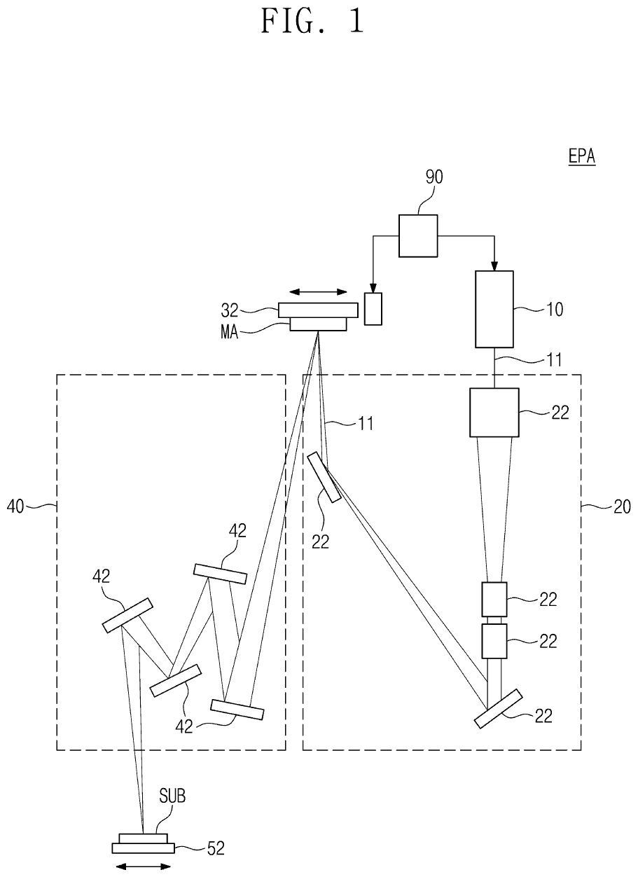

FIG. 1 is a schematic diagram showing an EUV exposure apparatus according to embodiments of the inventive concept. Referring to FIG. 1, an EUV exposure apparatus EPA may include a light source unit 10, a condenser unit 20, a projection unit 40, and a control unit 90. The light source unit 10, also described as a light source, may generate extreme ultraviolet (EUV) light, for example, light with a wavelength of 4 nm to 124 nm. In one embodiment, the light source unit 10 may generate EUV light, for example, light with a wavelength of 13.5 nm. The light source unit 10 may generate light having energy of 6.21 eV to 124 eV, specifically 90 e V to 95 eV.

The light source unit 10 generates EUV light, but may undesirably generate DUV light, for example, light with a wavelength of 100 nm or more and 300 nm or less. The condenser unit 20 serves to guide the light 11 generated from the light source unit 10 such that the light is reflected by a reflective mask MA mounted on a mask stage 32.

The condenser unit 20 includes condenser optics 22, for example, a lens or a mirror. The condenser optics 22 collects and reflects the light 11 and guides the light 11 to the reflective mask MA. The light 11 may be obliquely incident on the reflective mask MA through the condenser unit 20. The mask stage 32 may move the reflective mask MA depending on a scan direction of the reflective mask MA. The light source unit 10 and the mask stage 32 may be controlled by the control unit 90.

The light 11 incident on the reflective mask MA may be reflected by the reflective mask MA and may be obliquely incident on the projection unit 40. The projection unit 40 serves to project a mask pattern (absorption pattern) of the reflective mask MA onto a substrate SUB located on a substrate stage 52. For example, the substrate SUB may be a silicon wafer on which an integrated circuit is formed. A photoresist capable of reacting to light is coated on the substrate SUB. The substrate stage 52 may move the substrate SUB to change an exposure region (or exposure position) of the substrate SUB.

The projection unit 40 includes reflective projection optics 42, such as a lens. The reflective projection optics 42 uses the light 11 obliquely reflected from the reflective mask MA to reduce the mask pattern on the reflective mask MA by a certain magnification, for example, 4 times, 6 times, or 8 times, which is projected onto the substrate SUB.

In this case, a patterning process to form a desired pattern on the wafer may be performed using the mask pattern of the reflective mask MA. According to one embodiment of the inventive concept, the patterning process may include a lithography process using extreme ultraviolet (EUV). In this specification, extreme ultraviolet (EUV) may refer to ultraviolet rays having a wavelength of 4 nm and 124 nm, specifically 4 nm and 20 nm, and more specifically, 13.5 nm. Extreme ultraviolet (EUV) may refer to light having energy of 6.21 eV to 124 eV, specifically 90 e V to 95 eV.

A lithography process using extreme ultraviolet (EUV) may include an exposure and

development process using extreme ultraviolet (EUV) irradiated onto a photoresist layer. As an example, the photoresist layer may include metal oxide.

The photoresist layer may be formed to have a relatively thin thickness. Photoresist patterns may be formed by developing the photoresist layer exposed to extreme ultraviolet (EUV). The photoresist patterns may be metal oxide resist (MOR). When viewed in a two-dimensional perspective view, the photoresist patterns may have a line shape extending in one direction, an island shape, a zigzag shape, a honeycomb shape, or a circle shape, but are not limited thereto.

The mask patterns may be formed by patterning the photoresist patterns as an etch mask and one or more mask layers stacked therebelow. A target layer may be patterned using the mask patterns as an etch mask, and thus desired patterns may be formed on the wafer.

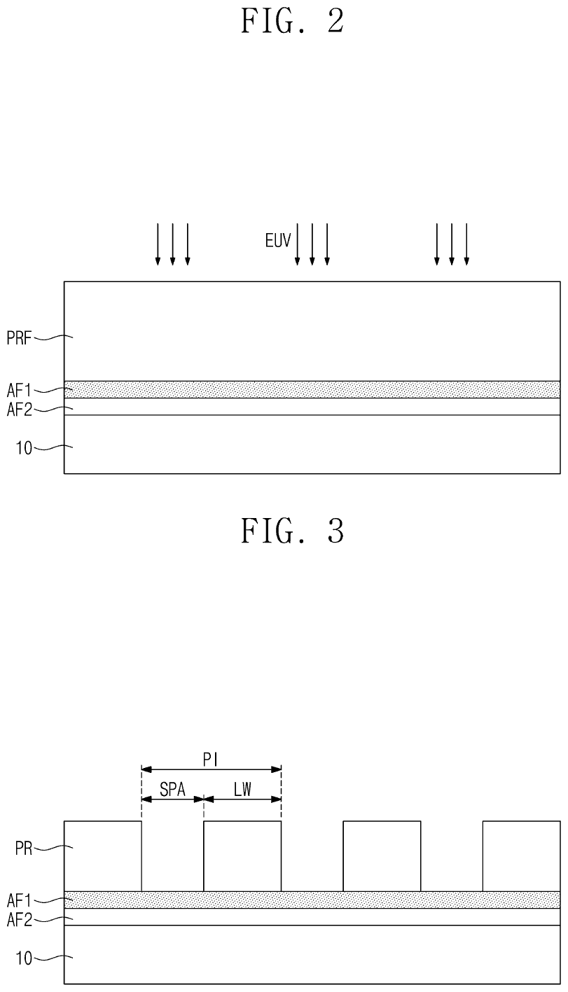

FIGS. 2 to 8 are cross-sectional views for explaining a photolithography process according to embodiments of the inventive concept.

Referring to FIG. 2, a substrate 10 may be provided. The substrate 10 is not particularly limited, but may be a semiconductor wafer such as a silicon wafer. First and second anti-reflection patterns AF1 and AF2 may be formed on the substrate 10. The second anti-reflection pattern AF2 may be interposed between the substrate 10 and the first anti-reflection pattern AF1. For example, the first anti-reflection pattern may be a bottom anti-reflective coating (BARC). The second anti-reflection pattern may be spin on carbon (SOC).

The first and second anti-reflection patterns AF1 and AF2 are provided below a photoresist pattern PR to prevent diffuse reflection of light passing through the photoresist pattern PR and to prevent the photoresist pattern PR from collapsing. The first and second anti-reflection patterns AF1 and AF2 may be omitted.

A photoresist layer PRF may be formed on the first anti-reflection pattern AF1. The photoresist layer PRF may include a photosensitive compound and a synthetic resin that is capable of being exposed and developed by extreme ultraviolet EUV. The photoresist layer PRF may include metal oxide. A thickness of the photoresist layer PRF may be greater than a thickness of each of the first and second anti-reflection patterns AF1 and AF2, and may be greater than the combined thickness of the first and second anti-reflection patterns AF1 and AF2.

An exposure process using extreme ultraviolet EUV may be performed on the photoresist layer PRF. As an example, the extreme ultraviolet EUV may have a wavelength of about 13.5 nm, which allows fine pitch patterns to be implemented.

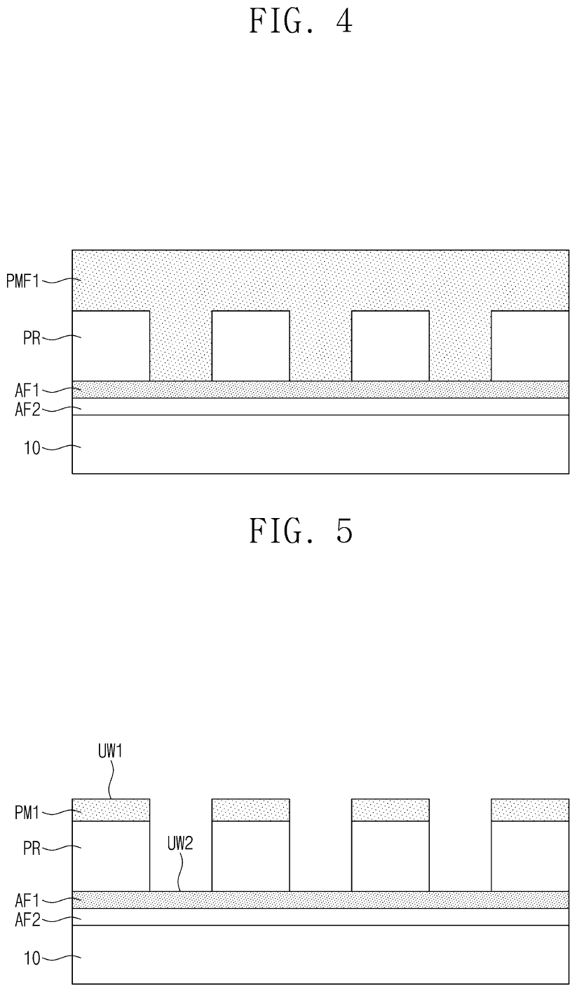

Referring to FIG. 3, photoresist patterns PR may be formed by developing a photoresist layer PRF exposed to extreme ultraviolet EUV. The photoresist patterns PR may have the same line width LW as each other. The photoresist patterns PR may have the same spacing SPA between them.

The photoresist patterns PR may be arranged in a first direction D1 at a constant pitch PI. The sum of the line width LW and the spacing SPA is defined as the pitch PI. For example, the pitch PI may be 22 nm to 26 nm. The line width LW and pitch PI may be variously changed depending on a type of illumination system used in the EUV lithography process.

Referring to FIG. 4, a first polymer layer PMF1 may be formed on the photoresist patterns PR and the first anti-reflection pattern AF1. The first polymer layer PMF1 may cover an upper surface and sidewalls of the photoresist patterns PR. The first polymer layer PMF1 may cover an upper surface of the first anti-reflection pattern AF1 exposed by the photoresist patterns PR.

Referring to FIG. 5, the first polymer layer PMF1 may be etched to form a first polymer pattern PM1 on the upper surface of the photoresist patterns PR. A line width of the first polymer pattern PM1 may be substantially the same as the line width of the photoresist patterns PR. A first material region may be formed at a surface of the first polymer pattern PM1. A second material region may be formed at a surface of the first anti-reflection pattern AF1. One of the first and second material regions may be polar, and the other may be non-polar. For example, the first material region may be non-polar due to the first polymer pattern PM1 being non-polar, and the second material region may be polar due to the photoresist patterns PR being polar.

The first polymer pattern PM1 may include a first upper surface UW1. As the first polymer layer PMF1 is etched, a second upper surface UW2 of the first anti-reflection pattern may be exposed. The first polymer layer PMF1 may include a material having a selective etch ratio with respect to the first anti-reflection pattern. The second upper surface UW2 may be disposed between adjacent photoresist patterns PR.

A level of the first upper surface UW1 (e.g. a vertical height above a top surface of the substrate 10) may be higher than a level of the second upper surface UW2. One of the first upper surface UW1 and the second upper surface UW2 may be polar, and the other may be non-polar. For example, the first upper surface UW1 may be non-polar, and the second upper surface UW2 may be polar. The first polymer pattern PM1 may include a first polymer. The first polymer may be a hydrophobic polymer. When the first polymer is a non-polar polymer, the first upper surface UW1 may be non-polar.

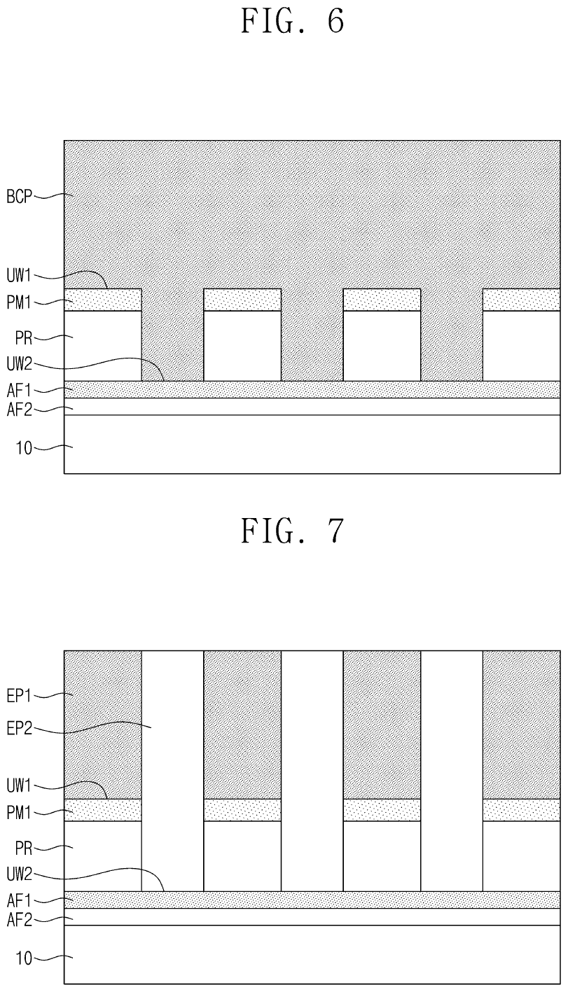

Referring to FIG. 6, a copolymer layer BCP may be formed on the first polymer pattern PM1 and the first anti-reflection pattern AF1. The copolymer layer BCP may cover the first upper surface UW1, the second upper surface UW2, and sidewalls of the photoresist patterns PR.

The copolymer layer BCP may include a first polymer and a second polymer. The first polymer and the second polymer may be different polymers. For example, one of the first polymer and the second polymer may be polar, and the other may be non-polar. For example, the first polymer may be polystyrene (PS), and the second polymer may be polymethyl methacrylate (PMMA).

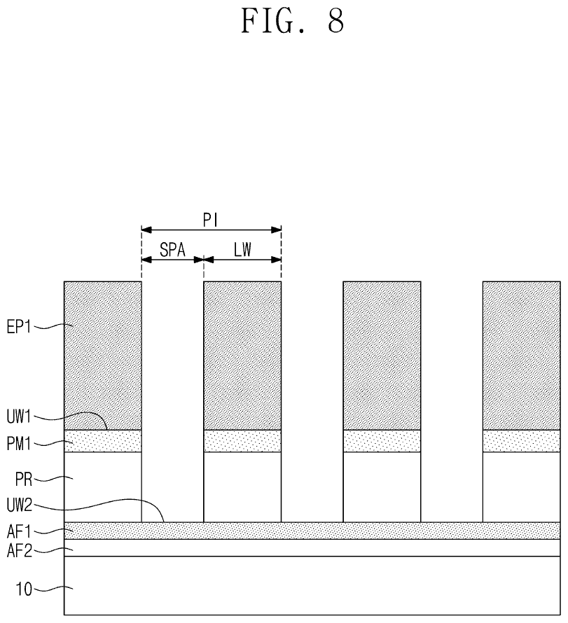

Referring to FIG. 7, the copolymer layer BCP may be phase-separated by performing an annealing process on the copolymer layer BCP. A directed self-assembly (DSA) process may be performed on the copolymer layer BCP. The copolymer layer BCP may be separated into a first polymer and a second polymer by an annealing process. A first extended pattern EP1 and a second extended pattern EP2 may be formed through the annealing process. In detail, the first polymer may be aligned in a vertical direction D3 on the first upper surface UW1 of the first polymer pattern PM1 to form the first extended pattern EP1. The second polymer may be aligned in the vertical direction D3 on the second upper surface UW2 to form a second extended pattern EP2. Aligning each polymer refers to changing the structure of the polymer to have a more crystalline arrangement, which can result in reducing the stress within the material.

The first extended pattern EP1 may include the first polymer, and the second extended pattern EP2 may include the second polymer. While performing the annealing process, the first polymer of the copolymer layer BCP may be aligned on the first upper surface UW1, and the second polymer may be aligned on the second upper surface UW2. For example, as the second extended pattern EP2 includes the polar second polymer, the second extended pattern EP2 may be aligned on the polar second upper surface UW2.

A line width of the first extended pattern EP1 may be substantially the same as the line width of the photoresist patterns PR and the line width of the first polymer pattern PM1. The second extended pattern EP2 may be formed between adjacent photoresist patterns PR.

Referring to FIG. 8, the second extended pattern EP2 may be selectively removed by performing an etching process. The etching process may have different etch rates for the first polymer and the second polymer. A spacing of the first extended patterns EP1 may be substantially the same as the spacing SPA of the photoresist patterns PR.

According to aspects of the inventive concept, the first polymer pattern PM1 and the first extended pattern EP1 may be formed on the photoresist patterns PR, thereby causing the photoresist patterns PR to extend in the vertical direction D3. Accordingly, even when some of the photoresist patterns PR are damaged or tilted, they may be corrected by the first extended pattern EP1.

Furthermore, according to aspects of the inventive concept, by forming the first polymer pattern PM1, the first and second extended patterns EP1 and EP2 may be more stably aligned during the annealing process. As the first polymer pattern PM1 is formed on the photoresist patterns PR, the DSA process may be performed without a process of etching the photoresist patterns PR.

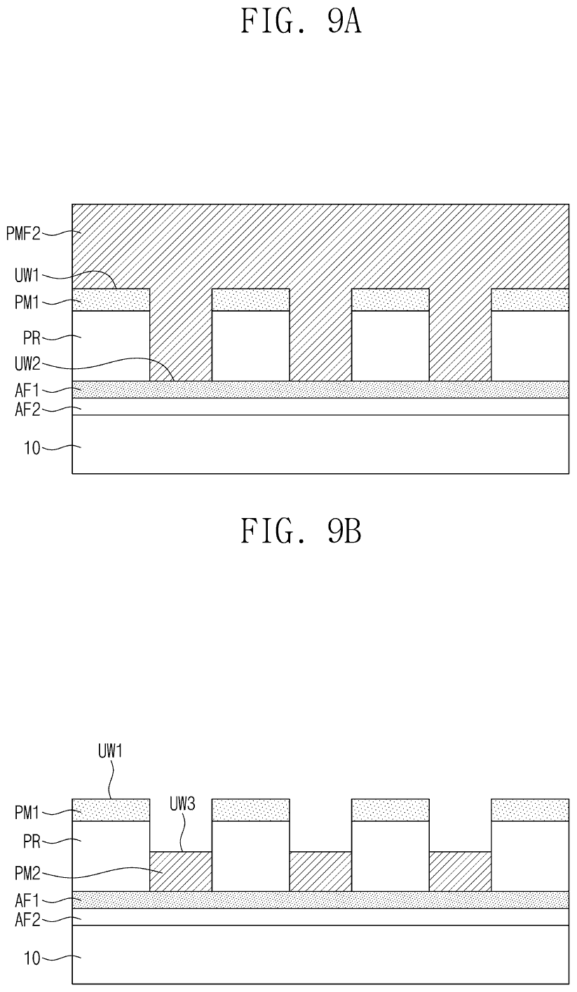

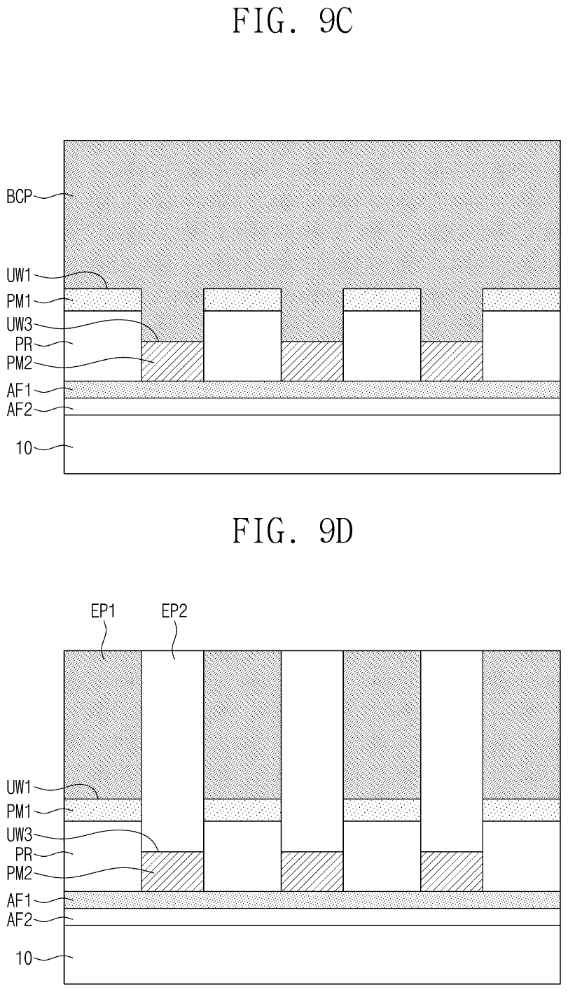

FIGS. 9A to 9D are cross-sectional views for explaining a photolithography process according to another embodiment of the inventive concept. After the process according to FIGS. 1 to 5, the process according to FIGS. 9A to 9D may proceed subsequently.

Referring to FIG. 9A, a second polymer layer PMF2 may be formed on the first polymer pattern PM1 and the first anti-reflection pattern AF1. The second polymer layer PMF2 may cover the first upper surface UW1, the second upper surface UW2, and the sidewalls of the photoresist patterns PR.

The second polymer layer PMF2 may include a second polymer. The second polymer may be a different polymer from the first polymer of the first polymer pattern PM1. For example, the first polymer may be polystyrene (PS), and the second polymer may be polymethyl methacrylate (PMMA).

Referring to FIG. 9B, the second polymer layer PMF2 may be etched to form a second polymer pattern PM2. As the second polymer layer PMF2 is etched, the first upper surface UW1 may be exposed again. The second polymer pattern PM2 may be formed on the second upper surface UW2 of FIG. 9A. The second polymer pattern PM2 may be formed between the photoresist patterns PR.

The second polymer pattern PM2 may include a third upper surface UW3. A level of the third upper surface UW3 may be lower than or equal to the level of the first upper surface UW1. One of the first upper surface UW1 and the third upper surface UW3 may be polar, and the other may be non-polar. For example, as the first polymer pattern PM1 includes a first polymer that is a non-polar polymer, the first upper surface UW1 may be non-polar. As the second polymer pattern PM2 includes a second polymer that is a polar polymer, the third upper surface UW3 may be polar.

Referring to FIG. 9C, a copolymer layer BCP may be formed on the first polymer pattern PM1 and the second polymer pattern PM2. The copolymer layer BCP may cover the first upper surface UW1, the third upper surface UW3, and the sidewalls of the photoresist patterns PR. Forming the copolymer layer BCP of FIG. 9C may be substantially the same as forming the copolymer layer BCP of FIG. 6.

Referring to FIG. 9D, the copolymer layer BCP may be phase-separated by performing an annealing process on the BCP. The annealing process of FIG. 9D may be substantially the same as the annealing process of FIG. 7. Through the annealing process, the first polymer may be aligned in the vertical direction D3 on the first upper surface UW1 of the first polymer pattern PM1 to form the first extended pattern EP1. Through the annealing process, the second polymer may be aligned in the vertical direction D3 on the third upper surface UW3 to form the second extended pattern EP2.

Referring to FIGS. 9A to 9D, the second polymer pattern PM2 may be further formed between the photoresist patterns PR. This is to form both the first polymer pattern PM1 and the second polymer pattern PM2 to further improve the alignment of each of the first and second polymers during the annealing process.

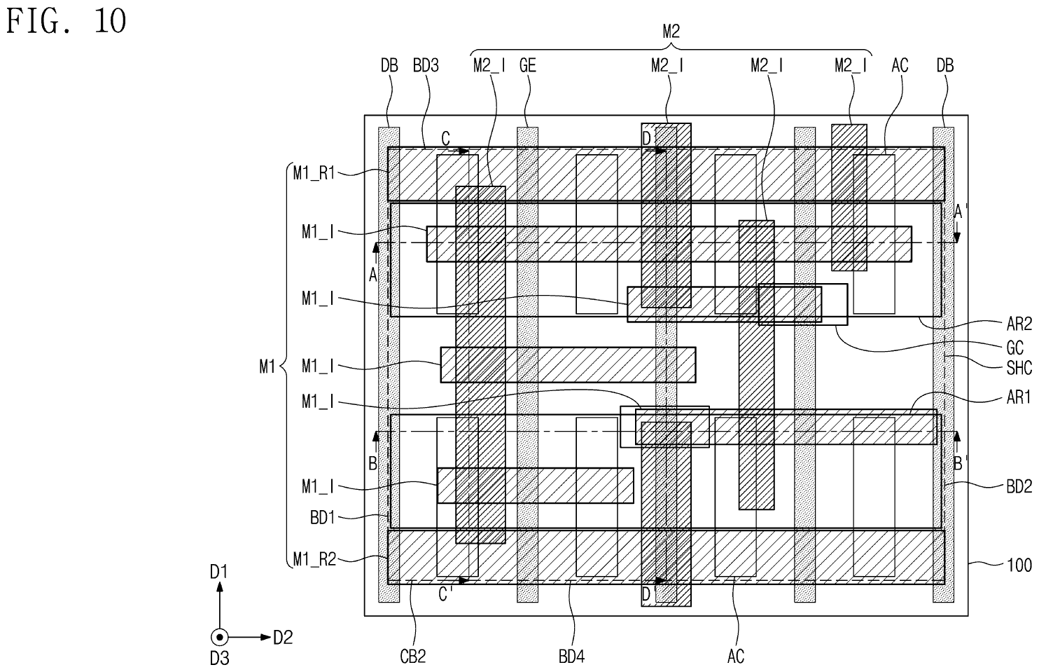

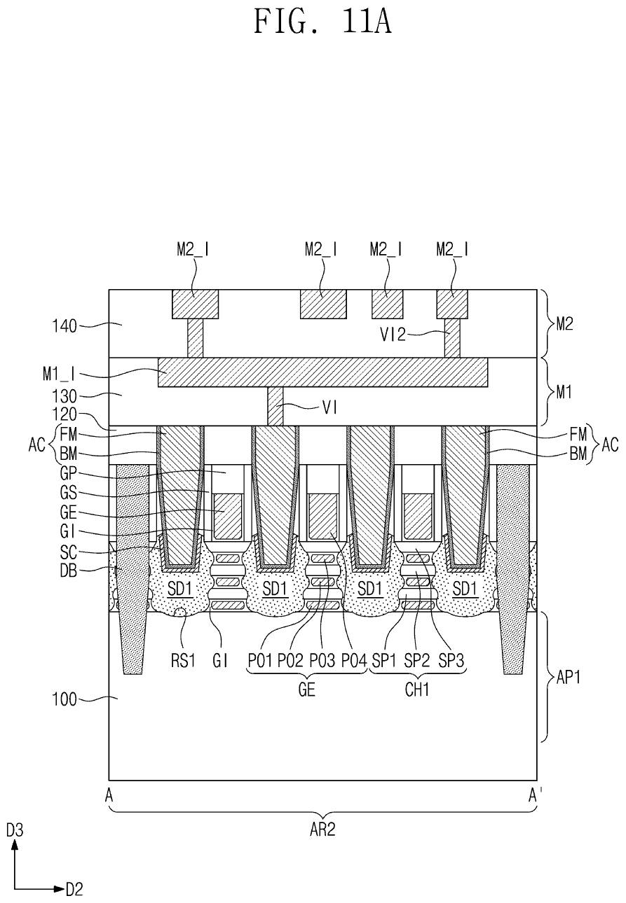

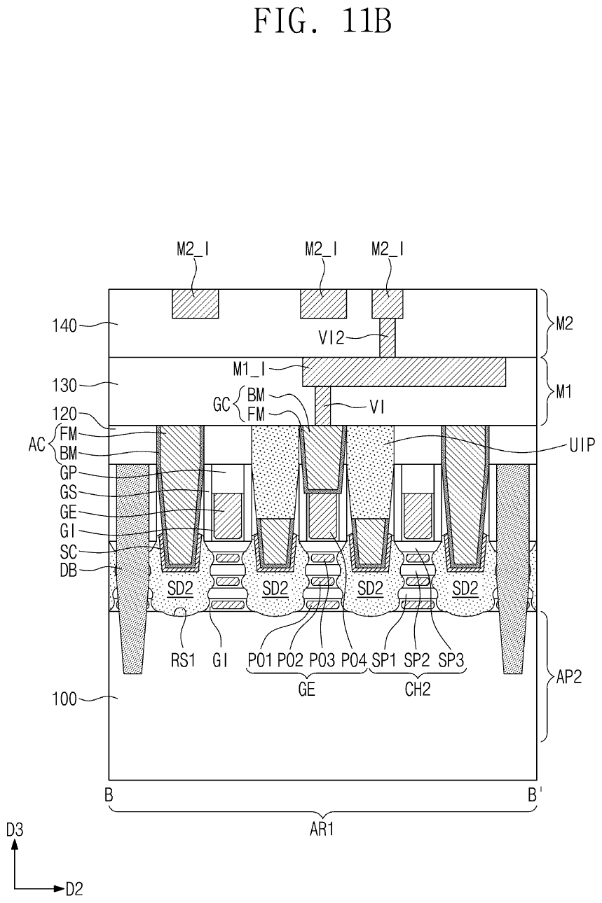

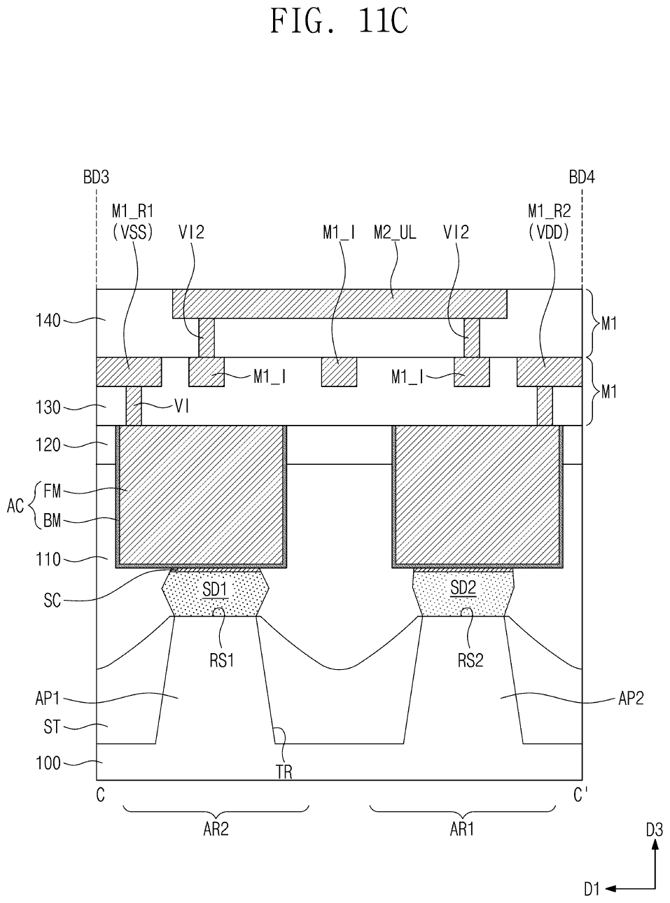

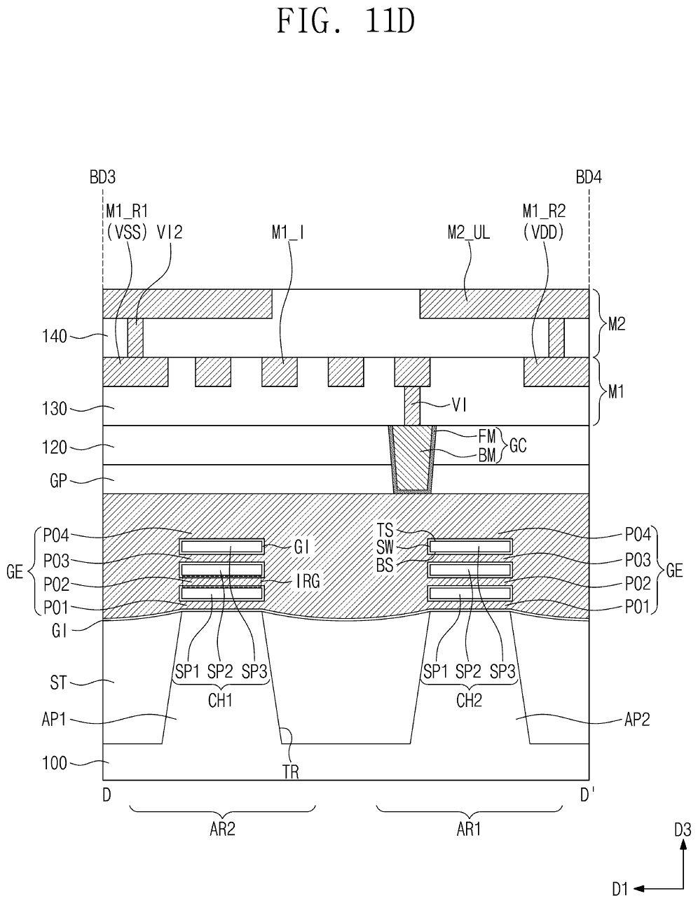

FIG. 10 is a plan view for explaining a semiconductor device according to embodiments of the inventive concept. FIGS. 11A to 11D are cross-sectional views taken in lines A-A′, B-B′, C-C′, and D-D′ of FIG. 10, respectively. FIGS. 10 and 11A to 11D are examples showing semiconductor devices in detail.

Referring to FIGS. 10 and 11A to 11D, a single height cell SHC is provided on a substrate 100. Logic transistors constituting a logic circuit may be disposed on a single height cell SHC. The substrate 100 may be a semiconductor substrate including silicon, germanium, silicon-germanium, etc., or a compound semiconductor substrate. As an example, the substrate 100 may be a silicon substrate.

The substrate 100 may include a first active region AR1 and a second active region AR2. Each of the first and second active regions AR1 and AR2 may extend in a second direction D2. In one embodiment, the first active region AR1 may be an NMOSFET region, and the second active region AR2 may be a PMOSFET region.

A first active pattern AP1 and a second active pattern AP2 may be defined by a trench TR formed on an upper portion of the substrate 100. The first active pattern AP1 may be provided on the first active region AR1, and the second active pattern AP2 may be provided on the second active region AR2. The first and second active patterns AP1 and AP2 may extend in the second direction D2. The first and second active patterns AP1 and AP2 may be portions of the substrate 100 and may be vertically protruding portions.

A device isolation layer ST may be provided on the substrate 100. The device isolation layer ST may fill the trench TR. The device isolation layer ST may include a silicon oxide layer. In one embodiment, the device isolation layer ST does not cover first and second channel patterns CH1 and CH2, which will be described later.

A first channel pattern CH1 may be provided on the first active pattern AP1. A second channel pattern CH2 may be provided on the second active pattern AP2. Each of the first channel pattern CH1 and the second channel pattern CH2 may include a first semiconductor pattern SP1, a second semiconductor pattern SP2, and a third semiconductor pattern SP3 sequentially stacked. The first to third semiconductor patterns SP1, SP2, and SP3 may be spaced apart from each other in a vertical direction (i.e., a third direction D3).

Each of the first to third semiconductor patterns SP1, SP2, and SP3 may include silicon (Si), germanium (Ge), or silicon-germanium (SiGe). For example, each of the first to third semiconductor patterns SP1, SP2, and SP3 may include crystalline silicon. In one embodiment of the inventive concept, the first to third semiconductor patterns SP1, SP2, and SP3 may be stacked nanosheets.

A plurality of first source/drain patterns SD1 may be provided on the first active pattern AP1. A plurality of first recesses RS1 may be formed on the first active pattern AP1. The first source/drain patterns SD1 may be provided in the first recesses RS1, respectively. The first source/drain patterns SD1 may be impurity regions of a second conductivity type (e.g., p-type). The first channel pattern CH1 may be interposed between a pair of first source/drain patterns SD1. For example, the stacked first to third semiconductor patterns SP1, SP2, and SP3 may connect a pair of first source/drain patterns SD1 to each other.

A plurality of second source/drain patterns SD2 may be provided on the second active pattern AP2. A plurality of second recesses RS2 may be formed on the second active pattern AP2. The second source/drain patterns SD2 may be provided in the second recesses RS2, respectively. The second source/drain patterns SD2 may be impurity regions of a first conductivity type (e.g., n-type). The second channel pattern CH2 may be interposed between a pair of second source/drain patterns SD2. For example, the stacked first to third semiconductor patterns SP1, SP2, and SP3 may connect a pair of second source/drain patterns SD2 to each other.

The first and second source/drain patterns SD1 and SD2 may be epitaxial patterns formed through a selective epitaxial growth (SEG) process. For example, an upper surface of each of the first and second source/drain patterns SD1 and SD2 may be higher than an upper surface of the third semiconductor pattern SP3. As another example, the upper surface of at least one of the first and second source/drain patterns SD1 and SD2 may be positioned at substantially the same level as the upper surface of the third semiconductor pattern SP3.

In one embodiment of the inventive concept, the first source/drain patterns SD1 may include a semiconductor element (e.g., SiGe) having a lattice constant greater than a lattice constant of the semiconductor element of the substrate 100. Accordingly, the pair of first source/drain patterns SD1 may provide compressive stress to the first channel pattern CH1 therebetween. The second source/drain patterns SD2 may include the same semiconductor element (e.g., Si) as that of the substrate 100.

Sidewalls of each of the first and second source/drain patterns SD1 and SD2 may have an uneven embossed shape. For example, the sidewalls of each of the first and second source/drain patterns SD1 and SD2 may have a wave-shaped profile. The sidewalls of each of the first and second source/drain patterns SD1 and SD2 may protrude toward first to third portions PO1, PO2, and PO3 of the gate electrode GE, which will be described later.

Gate electrodes GE may be provided crossing the first and second channel patterns CH1 and CH2 and extending in a first direction D1. The gate electrodes GE may be arranged in the second direction D2 and may have a first pitch. Each of the gate electrodes GE may vertically overlap the first and second channel patterns CH1 and CH2.

The gate electrode GE may include a first portion PO1 between the active pattern AP1 or AP2 and the first semiconductor pattern SP1, a second portion PO2 interposed between the first semiconductor pattern SP1 and the second semiconductor pattern SP2, a third portion PO3 interposed between the second semiconductor pattern SP2 and the third semiconductor pattern SP3, and a fourth portion PO4 on the third semiconductor pattern SP3.

Referring to FIG. 11D, the gate electrode GE may be provided on a top surface TS, bottom surface BS, and both sidewalls SW of each of the first to third semiconductor patterns SP1, SP2, and SP3. For example, a transistor according to this embodiment may be a three-dimensional field effect transistor (e.g., MBCFET or GAAFET) in which the gate electrode GE three-dimensionally surrounds the channel.

Referring again to FIGS. 10 and 11A to 11D, a pair of gate spacers GS may be disposed on opposite side walls of the fourth portion PO4 of each gate electrode GE. The gate spacers GS may extend in the first direction DI along the gate electrode GE. Upper surfaces of the gate spacers GS may be higher than upper surfaces of the gate electrode GE. The upper surfaces of the gate spacers GS may be coplanar with an upper surface of a first interlayer insulating layer 110, which will be described later. In one embodiment, the gate spacers GS may include at least one of SiCN, SiCON, and SiN. In another embodiment, the gate spacers GS may include a multi-layer formed of at least two of SiCN, SiCON, and SiN.

A gate capping pattern GP may be provided on the gate electrode GE. The gate capping pattern GP may extend in the first direction DI along the gate electrode GE. The gate capping pattern GP may include a material that has etch selectivity with respect to first and second interlayer insulating layers 110 and 120, which will be described later. In detail, the gate capping pattern GP may include at least one of SiON, SiCN, SiCON, and SiN.

The gate insulating layer GI may be interposed between the gate electrode GE and the first channel pattern CH1 and between the gate electrode GE and the second channel pattern CH2. The gate insulating layer GI may cover the top surface TS, bottom surface BS, and both sidewalls SW of each of the first to third semiconductor patterns SP1, SP2, and SP3. The gate insulating layer GI may cover an upper surface of the device isolation layer ST below the gate electrode GE.

Referring again to FIGS. 10 and 11A to 11D, the gate electrode GE may include a first metal pattern and a second metal pattern on the first metal pattern. The first metal pattern may be provided on the gate insulating layer GI and adjacent to the first to third semiconductor patterns SP1, SP2, and SP3. The first metal pattern may include a work function metal that adjusts the threshold voltage of the transistor. By adjusting a thickness and composition of the first metal pattern, the desired threshold voltage of the transistor may be achieved. For example, the first to third portions PO1, PO2, and PO3 of the gate electrode GE may be composed of a first metal pattern that is a work function metal.

The first metal pattern may include a metal nitride layer. For example, the first metal pattern may include nitrogen (N) and at least one metal selected from the group consisting of titanium (Ti), tantalum (Ta), aluminum (Al), tungsten (W), and molybdenum (Mo). Furthermore, the first metal pattern may further include carbon (C). The first metal pattern may include a plurality of work function metal layers stacked.

The second metal pattern may include a metal with lower resistance than the first metal pattern. For example, the second metal pattern may include at least one metal selected from the group consisting of tungsten (W), aluminum (Al), titanium (Ti), and tantalum (Ta). For example, the fourth portion PO4 of the gate electrode GE may include a first metal pattern and a second metal pattern on the first metal pattern.

A first interlayer insulating layer 110 may be provided on the substrate 100. The first interlayer insulating layer 110 may cover the gate spacers GS and the first and second source/drain patterns SD1 and SD2. An upper surface of the first interlayer insulating layer 110 may be substantially coplanar with an upper surface of the gate capping pattern GP and an upper surface of the gate spacer GS. A second interlayer insulating layer 120 may be disposed on the first interlayer insulating layer 110 to cover the gate capping pattern GP. A third interlayer insulating layer 130 may be provided on the second interlayer insulating layer 120.

A fourth interlayer insulating layer 140 may be provided on the third interlayer insulating layer 130. As an example, the first to fourth interlayer insulating layers 110 to 140 may include a silicon oxide layer.

The single height cell SHC may have a first boundary BD1 and a second boundary BD2 opposite each other in the second direction D2. The first and second boundaries BD1 and BD2 may extend in the first direction D1. The single height cell SHC may have a third boundary BD3 and a fourth boundary BD4 opposite each other in the first direction D1. The third and fourth boundaries BD3 and BD4 may extend in the second direction D2.

A pair of separation structures DB facing each other in the second direction D2 may be provided on opposite sides of the single height cell SHC. For example, a pair of separation structures DB may be provided on the first and second boundaries BD1 and BD2 of the single height cell SHC, respectively. The separation structure DB may extend parallel to the first and second gate electrodes GE1 and GE2 in the first direction D1. A pitch between the separation structure DB and the first and second gate electrodes GE1 and GE2 adjacent thereto may be the same as the first pitch.

The separation structure DB may extend through the first and second interlayer insulating layers 110 and 120 and into the first and second active patterns AP1 and AP2. The separation structure DB may penetrate an upper portion of each of the first and second active patterns AP1 and AP2. The separation structure DB may electrically separate the active region of the single height cell SHC from the active region of other adjacent cells.

Active contacts AC may be provided through the first and second interlayer insulating layers 110 and 120 and may be electrically connected to the first and second source/drain patterns SD1 and SD2, respectively. A pair of active contacts AC may be provided on both sides of the gate electrode GE. When viewed in a plan view, the active contact AC may have a bar shape extending in the first direction D1.

The active contact AC may be a self-aligned contact. That is, the active contact AC may be formed in a self-aligned manner using the gate capping pattern GP and the gate spacer GS. For example, the active contact AC may cover at least a portion of the sidewall of the gate spacer GS. Although not shown, the active contact AC may cover a portion of an upper surface of the gate capping pattern GP.

A metal-semiconductor compound layer SC, for example, a silicide layer, may be interposed between the active contact AC and the first source/drain pattern SD1 and between the active contact AC and the second source/drain pattern SD2, respectively. The active contact AC may be electrically connected to the source/drain patterns SD1 and SD2 through the metal-semiconductor compound layer SC. For example, the metal-semiconductor compound layer SC may include at least one of titanium-silicide, tantalum-silicide, tungsten-silicide, nickel-silicide, and cobalt-silicide.

Gate contacts GC may be provided through the second interlayer insulating layer 120 and the gate capping pattern GP and electrically connected to the gate electrodes GE, respectively. When viewed in a plan view, the gate contacts GC may be arranged to overlap the first active region AR1 and the second active region AR2, respectively. As an example, the gate contact GC may be provided on the second active pattern AP2 (refer to FIG. 11B).

In one embodiment of the inventive concept, referring to FIG. 11B, the upper portion of the active contact AC directly adjacent to the gate contact GC may be filled with an upper insulating pattern UIP. A bottom surface of the upper insulating pattern UIP may be lower than a bottom surface of the gate contact GC. An upper surface of the active contact AC adjacent to the gate contact GC may be lower than the bottom surface of the gate contact GC with the upper insulating pattern UIP filling the vertical space therebetween. As a result, it is possible to prevent a short circuit occurring when the gate contact GC is in contact with the adjacent active contact AC.

Each of the active contact AC and the gate contact GC may include a conductive pattern FM and a barrier pattern BM surrounding the conductive pattern FM. For example, the conductive pattern FM may include at least one metal selected from aluminum, copper, tungsten, molybdenum, and cobalt. The barrier pattern BM may cover sidewalls and bottom surface of the conductive pattern FM. The barrier pattern BM may include a metal layer/metal nitride layer. The metal layer may include at least one of titanium, tantalum, tungsten, nickel, cobalt, and platinum. The metal nitride layer may include at least one of titanium nitride (TiN), tantalum nitride (TaN), tungsten nitride (WN), nickel nitride (NiN), cobalt nitride (CON), and platinum nitride (PtN).

A first metal layer M1 may be provided in the third interlayer insulating layer 130. For example, the first metal layer M1 may include a first power wiring M1_R1, a second power wiring M1_R2, and first wirings MI_I. Each of the wirings M1_R1, M1_R2, and MI_I of the first metal layer M1 may extend parallel to each other in the second direction D2.

In detail, the first and second power wirings M1_R1 and M1_R2 may be provided on the third and fourth boundaries BD3 and BD4 of the single height cell SHC, respectively. The first power wiring M1_R1 may extend in the second direction D2 in the third boundary BD3. The second power wiring M1_R2 may extend in the second direction D2 in the fourth boundary BD4.

The first wirings M1_I of the first metal layer M1 may be disposed between the first and second power wirings M1_R1 and M1_R2. The first wirings M1_I of the first metal layer M1 may be arranged in the first direction DI with a second pitch. The second pitch may be smaller than the first pitch. A line width of each of the first wirings M1_I may be smaller than a line width of each of the first and second power wirings M1_R1 and M1_R2.

The first metal layer M1 may further include first vias VI. The first vias VI may be provided under the wirings M1_R1, M1_R2, and M1_I of the first metal layer M1, respectively. The active contact AC and the wiring of the first metal layer MI may be electrically connected to each other through the first via VI. The gate contact GC and the wiring of the first metal layer M1 may be electrically connected to each other through the first via VI.

A second metal layer M2 may be provided in the fourth interlayer insulating layer 140. The second metal layer M2 may include a plurality of second wirings M2_I. Each of the second wirings M2_I of the second metal layer M2 may have a line shape or a bar shape extending in the first direction D1. The second wirings M2_I may extend parallel to each other in the first direction D1.

The second metal layer M2 may further include second vias VI2 respectively provided below the second wirings M2_I. The wiring of the first metal layer M1 and the wiring of the second metal layer M2 may be electrically connected to each other through the second via VI2.

For example, the wiring of the second metal layer M2 and the second via VI2 therebelow may be formed together through a dual damascene process.

The wiring of the first metal layer M1 and the wiring of the second metal layer M2 may include the same or different conductive materials. For example, the wiring of the first metal layer M1 and the wiring of the second metal layer M2 may include at least one metal material selected from aluminum, copper, tungsten, molybdenum, ruthenium, and cobalt. Although not shown, metal layers (e.g., M3, M4, M5 . . . ) stacked on the fourth interlayer insulating layer 140 may be additionally disposed. Each of the stacked metal layers may include wirings for routing between cells.

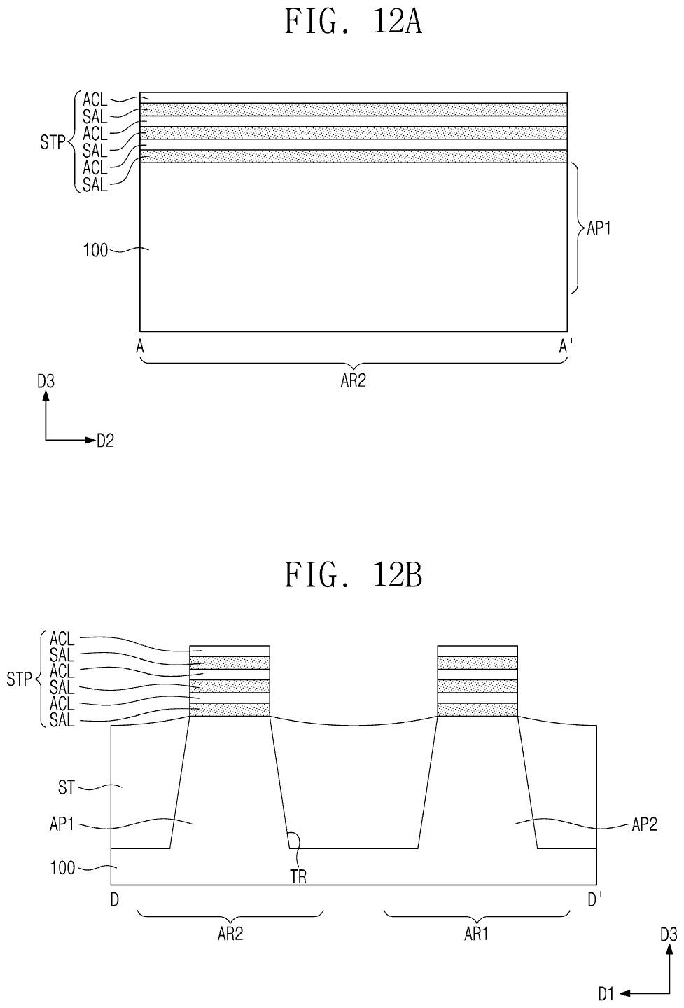

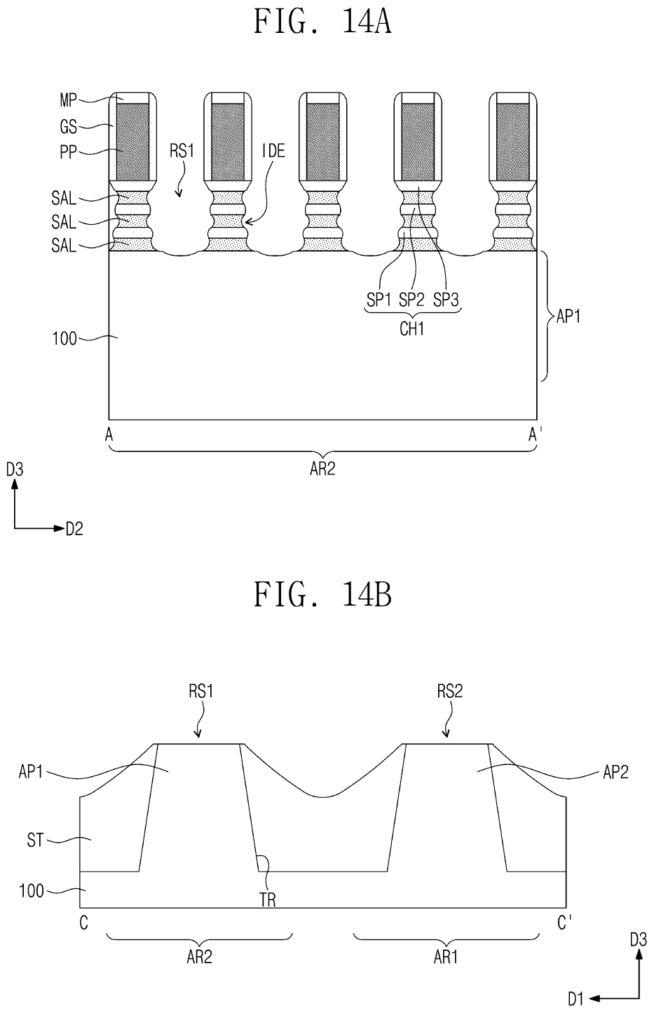

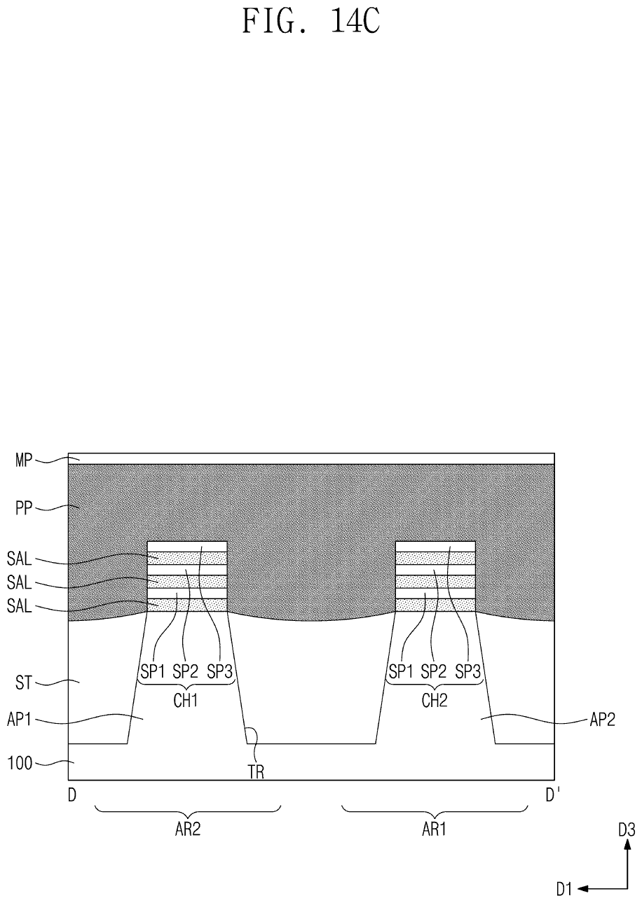

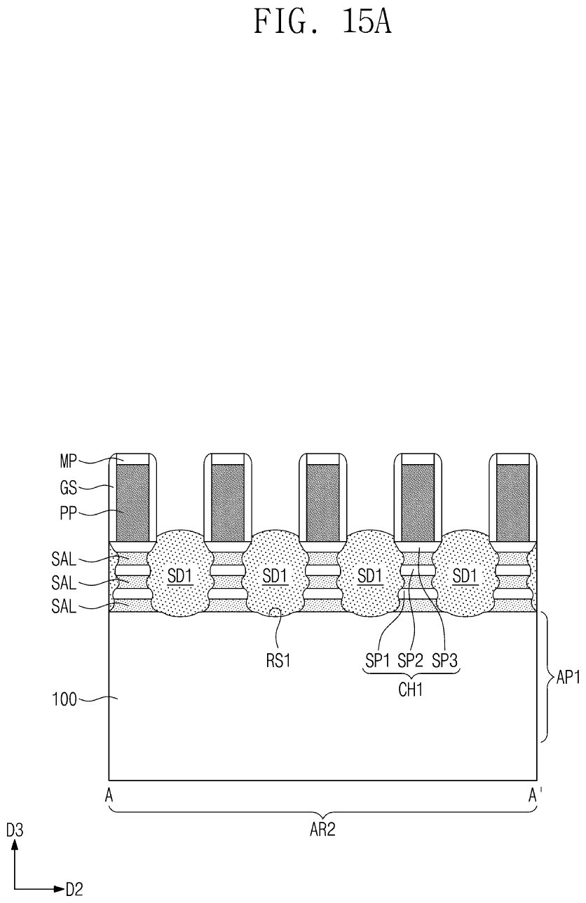

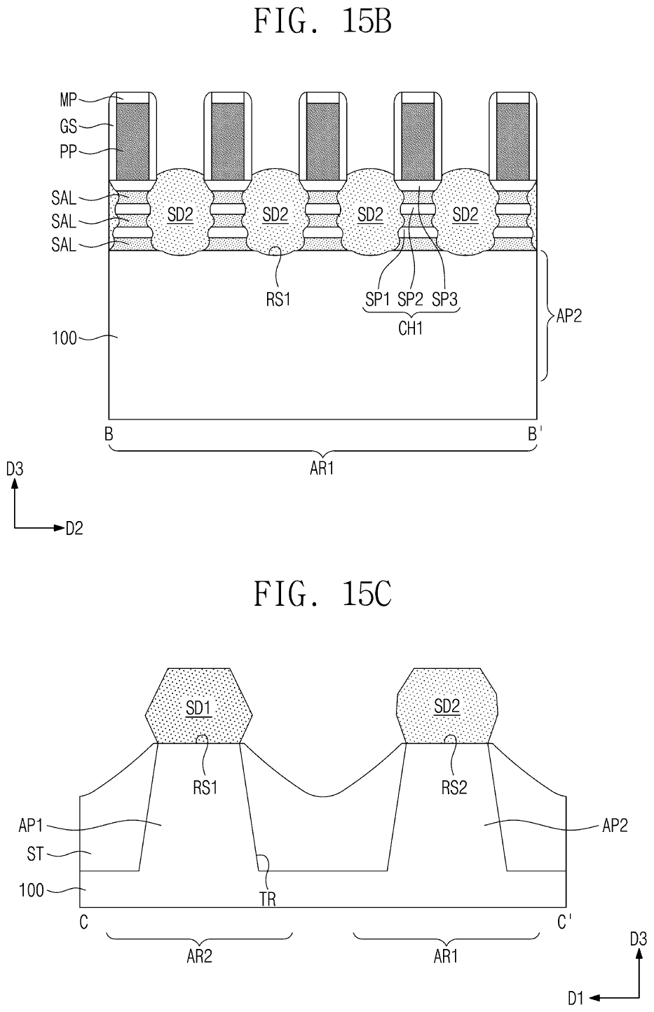

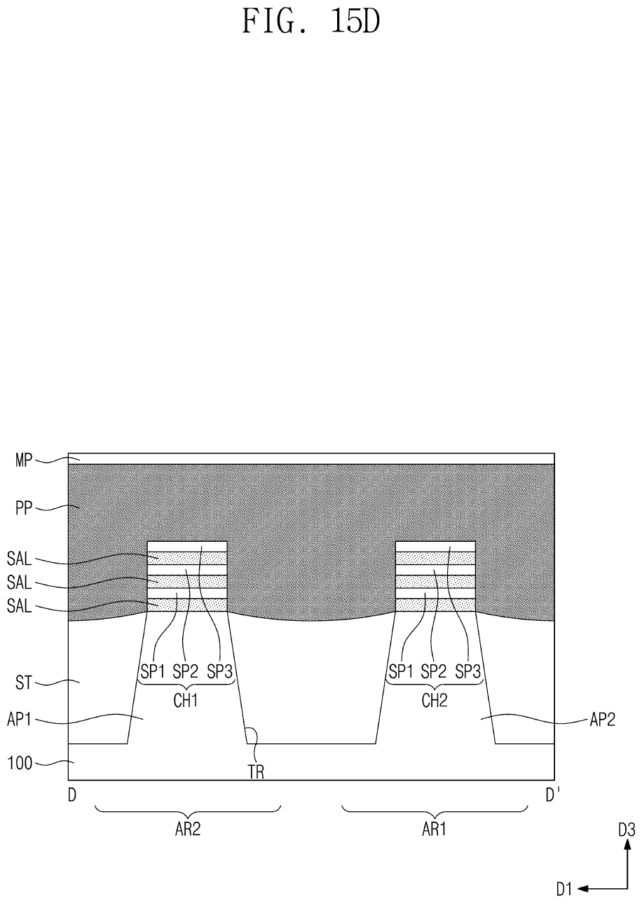

FIGS. 12A to 17C are cross-sectional views for explaining a method of manufacturing a semiconductor device, such as depicted in FIG. 10, according to embodiments of the inventive concept. FIGS. 12A, 13A, 14A, 15A, 16A and 17A are cross-sectional views taken in line A-A′. FIG. 15B is a cross-sectional view taken in line B-B′. FIGS. 14B, 15C, 16B and 17B are cross-sectional views taken in line C-C′. FIGS. 12B, 13B, 14C, 15D, 16C and 17C are cross-sectional views taken in line D-D′.

Referring to FIGS. 12A and 12B, a substrate 100 including first and second active regions AR1 and AR2 may be provided. Active layers ACL and sacrificial layers SAL alternately stacked may be formed on the substrate 100. The active layers ACL may include one of silicon (Si), germanium (Ge), and silicon-germanium (SiGe), and the sacrificial layers SAL may include another one of silicon (Si), germanium (Ge), and silicon-germanium (SiGe).

The sacrificial layer SAL may include a material that may have an etch selectivity with respect to the active layer ACL. For example, the active layers ACL may include silicon (Si), and the sacrificial layers SAL may include silicon-germanium (SiGe). A concentration of germanium (Ge) in each of the sacrificial layers SAL may be 10 at % to 30 at %.

Mask patterns may be formed on the first and second active regions AR1 and AR2 of the substrate 100, respectively. A patterning process may be performed using the mask patterns as an etch mask to form a trench TR defining a first active pattern AP1 and a second active pattern AP2. A detailed description of the patterning process will be described later. The first active pattern AP1 may be formed on the first active region AR1. The second active pattern AP2 may be formed on the second active region AR2.

A stacked pattern STP may be formed on each of the first and second active patterns AP1 and AP2. The stacked pattern STP may include active layers ACL and sacrificial layers SAL alternately stacked with each other. The stacked pattern STP may be formed together with the first and second active patterns AP1 and AP2 during the patterning process.

A device isolation layer ST may be formed to fill the trench TR. In detail, an insulating layer may be formed on the entire surface of the substrate 100 to cover the first and second active patterns AP1 and AP2 and the stacked patterns STP. The insulating layer may be recessed until the stacked patterns (STP) are exposed to form the device isolation layer ST.

The device isolation layer ST may include an insulating material such as a silicon oxide layer. The stacked patterns STP may be exposed on the device isolation layer ST. The stacked patterns STP may protrude vertically above the device isolation layer ST.

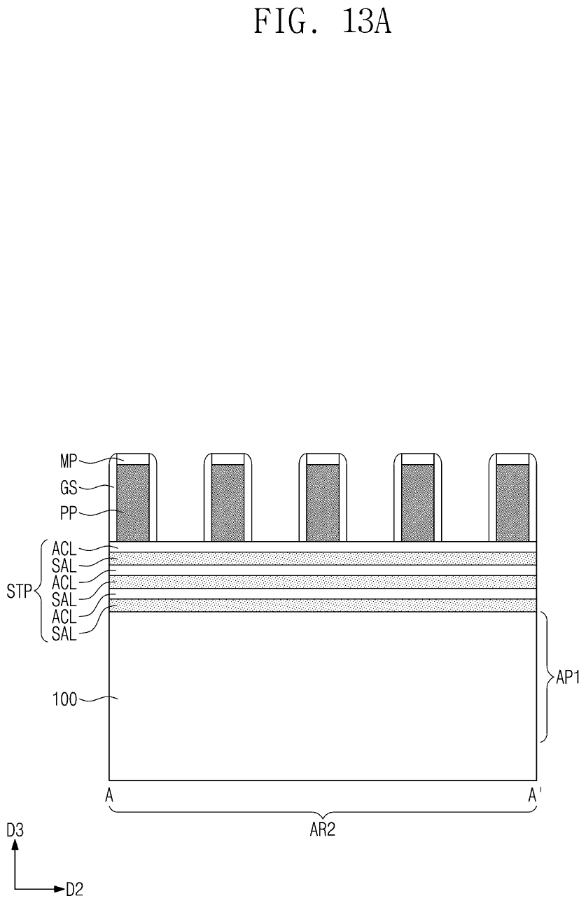

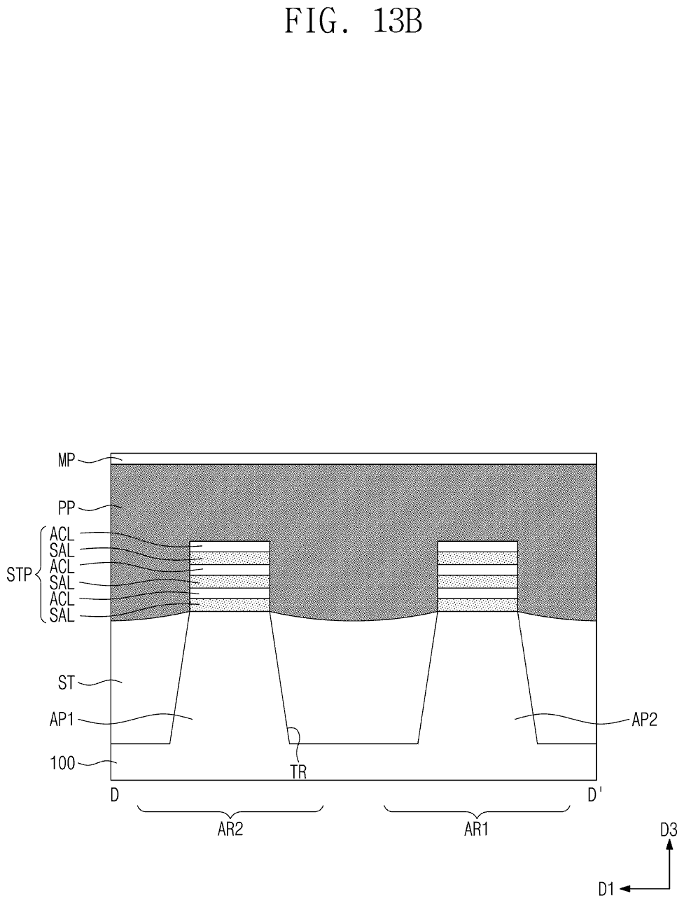

Referring to FIGS. 13A and 13B, sacrificial patterns PP may be formed across the stacked patterns STP on the substrate 100. Each of the sacrificial patterns PP may be formed in a line shape or a bar shape extending in the first direction D1. The sacrificial patterns PP may be arranged in the second direction D2 with a first pitch.

In detail, forming the sacrificial patterns PP may include forming a sacrificial layer on the entire surface of the substrate 100, forming hard mask patterns MP on the sacrificial layer, and patterning the sacrificial layer using the hard mask patterns MP an etch mask. The sacrificial layer may include polysilicon.

A pair of gate spacers GS may be formed on opposite sidewalls of each of the sacrificial patterns PP. Forming the gate spacers GS may include conformally forming a gate spacer layer on the entire surface of the substrate 100 and anisotropically etching the gate spacer layer.

Referring to FIGS. 14A to 14C, first recesses RS1 may be formed in the stacked pattern STP on the first active pattern AP1. Second recesses RS2 may be formed in the stacked pattern STP on the second active pattern AP2. While forming the first and second recesses RS1 and RS2, the device isolation layer ST on both sides of the first and second active patterns AP1 and AP2 may be further recessed (refer to FIG. 14B).

In detail, the stacked pattern STP on the first active pattern AP1 may be etched using the hard mask patterns MP and the gate spacers GS as an etch mask to form the first recesses RS1. The first recess RS1 may be formed between a pair of sacrificial patterns PP. Forming the first recess RS1 may include additionally performing a selective etching process on the exposed sacrificial layers SAL. Accordingly, the first recess RS1 may have a wavy inner wall.

The second recesses RS2 in the stacked pattern STP on the second active pattern AP2 may be formed in the same manner as the first recesses RS1. However, forming the second recess RS2 may further include forming an inner spacer IP in the region where the sacrificial layer SAL is recessed. As a result, the inner wall of the second recess RS2 may not have a wavy shape like the inner wall of the first recess RS1.

First to third semiconductor patterns SP1, SP2, and SP3 sequentially stacked between adjacent first recesses RS1 may be formed from the active layers ACL, respectively. First to third semiconductor patterns SP1, SP2, and SP3 may be formed sequentially stacked between adjacent second recesses RS2, may be formed from the active layers ACL, respectively. The first to third semiconductor patterns SP1, SP2, and SP3 between adjacent first recesses RS1 may form a first channel pattern CH1. The first to third semiconductor patterns SP1, SP2, and SP3 between adjacent second recesses RS2 may form a second channel pattern CH2.

Referring to FIGS. 15A to 15D, first source/drain patterns SD1 may be formed in the first recesses RS1, respectively. In detail, an SEG process using the inner wall of the first recess RS1 as a seed layer may be performed to form an epitaxial layer that fills the first recess RS1. The epitaxial layer may be grown using the first to third semiconductor patterns SP1, SP2, and SP3 exposed by the first recess RS1 and the substrate 100 as seeds. As an example, the SEG process may include a chemical vapor deposition (CVD) process or a molecular beam epitaxy (MBE) process.

In one embodiment of the inventive concept, the first source/drain pattern SD1 may include a semiconductor element (e.g., SiGe) having a lattice constant greater than the lattice constant of the semiconductor element of the substrate 100. While the first source/drain pattern SD1 is formed, impurities (e.g., boron, gallium, or indium) that cause the first source/drain pattern SD1 to have a p-type may be injected in-situ. As another example, after the first source/drain pattern SD1 is formed, impurities may be injected into the first source/drain pattern SD1.

Second source/drain patterns SD2 may be formed in the second recesses RS2, respectively. In detail, a SEG process using the inner wall of the second recess RS2 may be performed as a seed layer to form the second source/drain pattern SD2.

In one embodiment of the inventive concept, the second source/drain pattern SD2 may include the same semiconductor element (e.g., Si) as the substrate 100. While the second source/drain pattern SD2 is formed, impurities (e.g., phosphorus, arsenic, or antimony) that cause the second source/drain pattern SD2 to be n-type may be injected in-situ. As another example, after the second source/drain pattern SD2 is formed, impurities may be injected into the second source/drain pattern SD2.

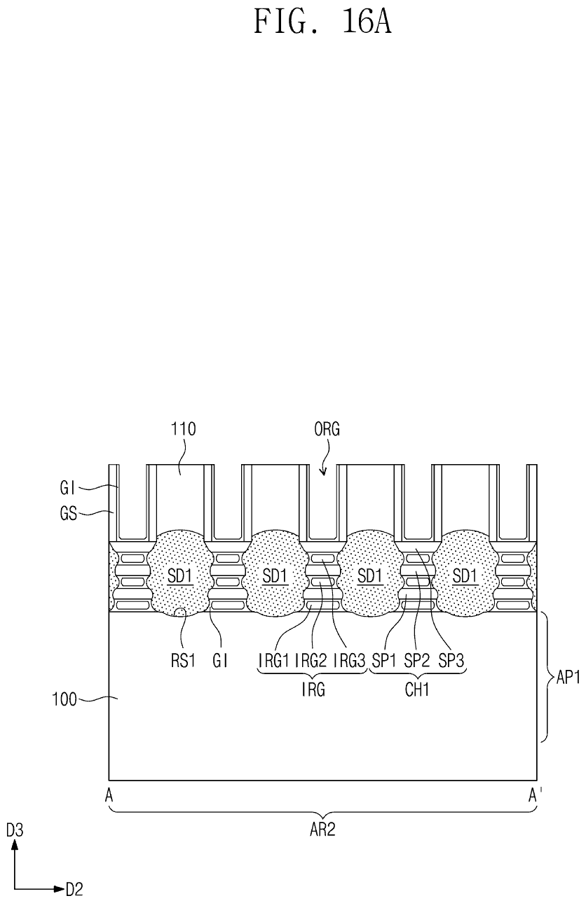

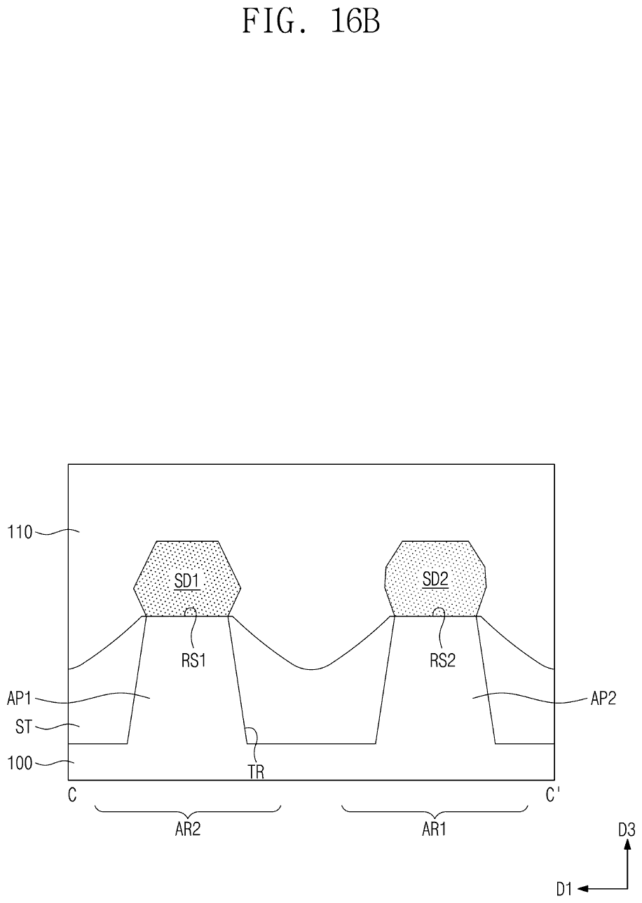

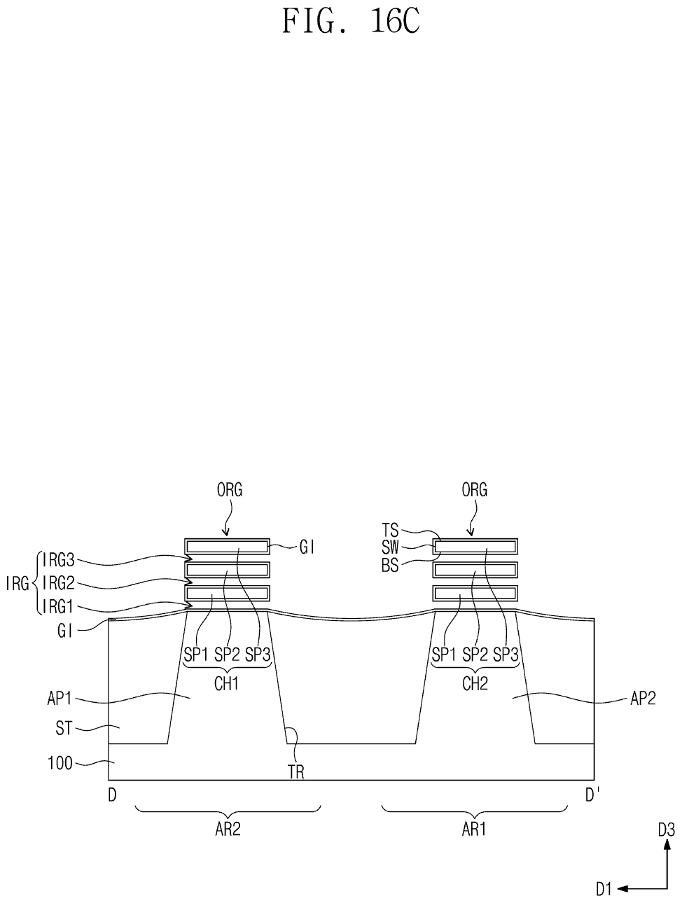

Referring to FIGS. 16A to 16C, a first interlayer insulating layer 110 may be formed to cover the first and second source/drain patterns SD1 and SD2, hard mask patterns MP, and gate spacers GS. As an example, the first interlayer insulating layer 110 may include a silicon oxide layer.

The first interlayer insulating layer 110 may be planarized until an upper surfaces of the sacrificial patterns PP are exposed. Planarization of the first interlayer insulating layer 110 may be performed using an etch back or chemical mechanical polishing (CMP) process. During the planarization process, all hard mask patterns MP may be removed. As a result, an upper surface of the first interlayer insulating layer 110 may be coplanar with the upper surfaces of the sacrificial patterns PP and the gate spacers GS.

One region of the sacrificial pattern (PP) may be selectively opened using lithography. For example, a region of the sacrificial pattern PP on the third and fourth boundaries BD3 and BD4 of the first single height cell SHC1 may be selectively opened. The open region of the sacrificial pattern PP may be removed by selectively etching. A gate cutting pattern CT may be formed by filling a space where the sacrificial pattern PP is removed with an insulating material.

The exposed sacrificial patterns PP may be selectively removed. The sacrificial patterns PP may be removed, and thus an outer region ORG exposing the first and second channel patterns CH1 and CH2 may be formed (refer to FIG. 16C). Removing the sacrificial patterns PP may include wet etching using an etchant that selectively etch polysilicon.

The sacrificial layers SAL exposed through the outer region ORG may be selectively removed to form inner regions IRG (refer to FIG. 16C). In detail, an etching process may be performed to selectively etch the sacrificial layers SAL, and thus only the sacrificial layers SAL may be removed while leaving the first to third semiconductor patterns SP1, SP2, and SP3 intact. The etching process may have a high etch rate for silicon-germanium having a relatively high germanium concentration. For example, the etching process may have a high etch rate for silicon-germanium with a germanium concentration greater than 10 at %.

During the etching process, the sacrificial layers SAL on the first and second active regions AR1 and AR2 may be removed. The etching process may be wet etching. The etching material used in the etching process may quickly remove the sacrificial layer SAL having a relatively high germanium concentration.

As selectively removing the sacrificial layers SAL, only the first to third semiconductor patterns SP1, SP2, and SP3 stacked on each of the first and second active patterns AP1 and AP2 may remain. First to third inner regions IRG1, IRG2, and IRG3 may be formed through the regions from which the sacrificial layers SAL are removed.

In detail, a first inner region IRG1 may be formed between the active pattern AP1 or AP2 and the first semiconductor pattern SP1, a second inner region IRG2 may be formed between the first semiconductor pattern SP1 and the second semiconductor pattern SP2, and a third inner region IRG3 may be formed between the second semiconductor pattern SP2 and the third semiconductor pattern SP3.

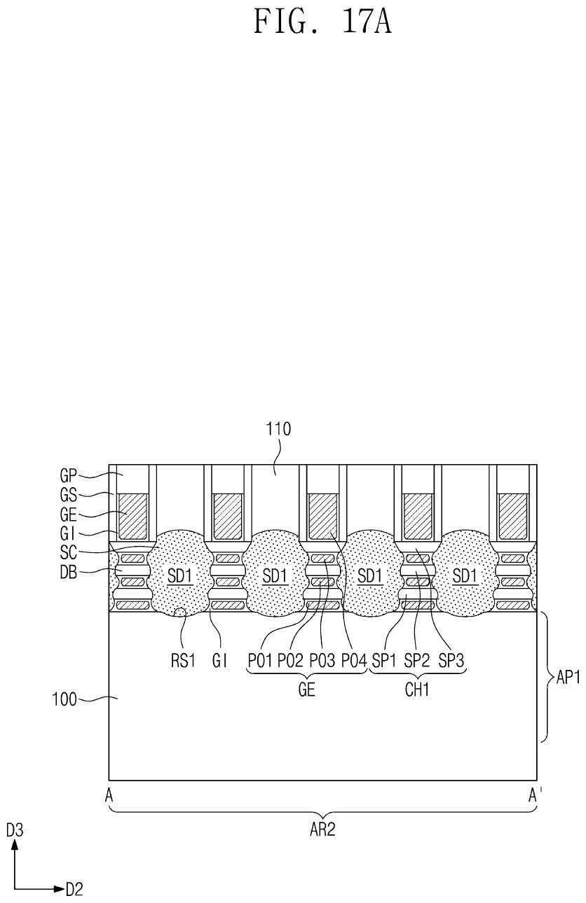

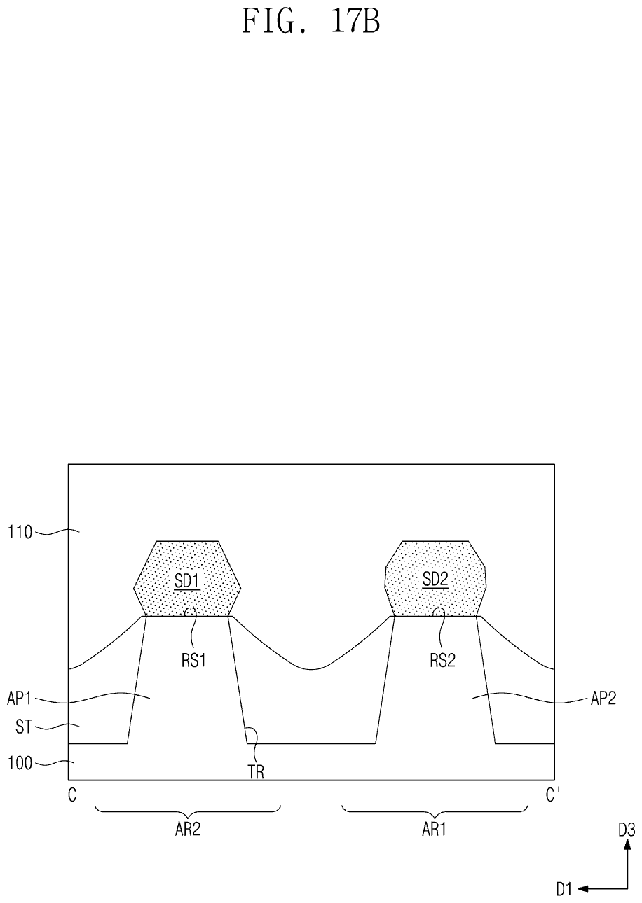

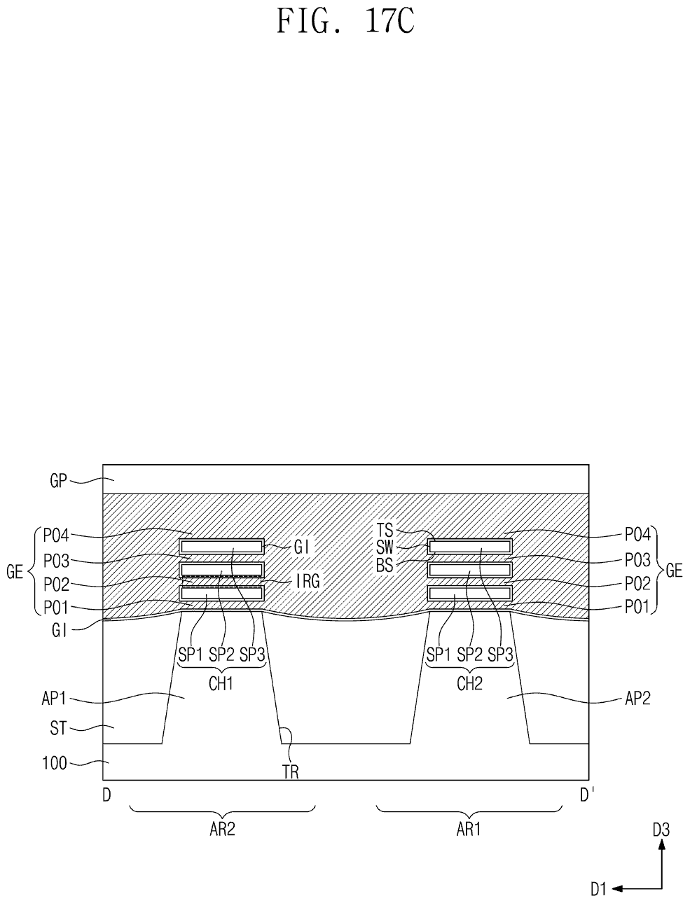

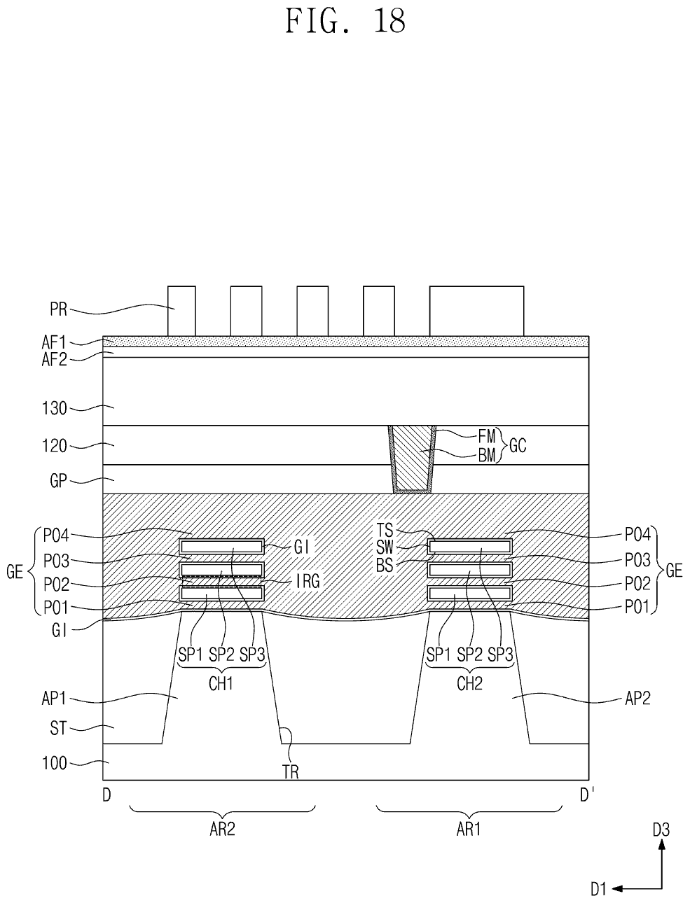

Referring to FIGS. 17A to 17C, a gate insulating layer GI may be conformally formed on the exposed first to third semiconductor patterns SP1, SP2, and SP3. A gate electrode GE may include first and third portions PO1, PO2, and PO3 respectively formed in the first and third inner regions IRG1, IRG2, and IRG3, and a fourth region PO4 formed in the outer region ORG. The gate electrode GE may be recessed, reducing its height. A gate capping pattern GP may be formed on the recessed gate electrode GE.

Referring again to FIGS. 10 and 11A to 11D, a second interlayer insulating layer 120 may be formed on the first interlayer insulating layer 110. The second interlayer insulating layer 120 may include a silicon oxide layer. Active contacts AC may be formed through the second interlayer insulating layer 120 and the first interlayer insulating layer 110 and electrically connected to the first and second source/drain patterns SD1 and SD2. A gate contact GC may be formed that penetrates the second interlayer insulating layer 120 and the gate capping pattern GP and is electrically connected to the gate electrode GE.

Forming each active contact AC and gate contact GC may include forming a barrier pattern BM and forming a conductive pattern FM on the barrier pattern BM. The barrier pattern BM may be formed conformally and may include a metal layer/metal nitride layer. The conductive pattern FM may include a low-resistance metal.

A pair of separation structures DB may be formed on both sides of each of the first and second single height cells SHC1 and SHC2. The separation structure DB may extend from the second interlayer insulating layer 120 through the gate electrode GE into the active pattern AP1 or AP2. The separation structure DB may include an insulating material such as a silicon oxide layer or a silicon nitride layer.

A third interlayer insulating layer 130 may be formed on the active contacts AC and the gate contacts GC. A first metal layer M1 may be formed in the third interlayer insulating layer 130. A fourth interlayer insulating layer 140 may be formed on the third interlayer insulating layer 130. A second metal layer M2 may be formed in the fourth interlayer insulating layer 140.

Referring to FIGS. 18 to 25, a semiconductor device to which an embodiment of the inventive concept is applied and its manufacturing method will be described in detail.

FIGS. 18 to 25 are cross-sectional views for explaining the method of forming FIG. 11D. With reference to FIGS. 18 to 25, the method of forming the first metal layer M1 will be described in more detail. Forming the first metal layer M1 may include the photolithography process described with reference to FIGS. 2 to 9D.

Referring to FIG. 18, first and second anti-reflection patterns AF1 and AF2 may be formed on the third interlayer insulating layer 130. The second anti-reflection pattern AF2 may be interposed between the third interlayer insulating layer 130 and the first anti-reflection pattern AF1. A photoresist pattern PR may be formed on the first anti-reflection pattern AF1. Forming the photoresist pattern PR may be performed through the photolithography process using extreme ultraviolet (EUV) previously described in FIGS. 2 and 3. As another example, line widths of the photoresist patterns PR may be different.

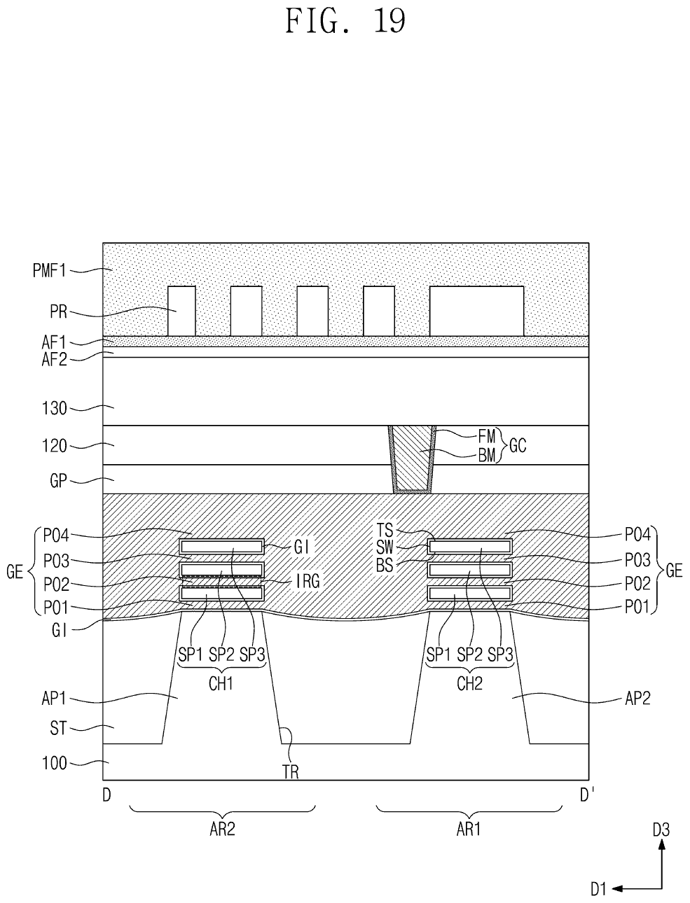

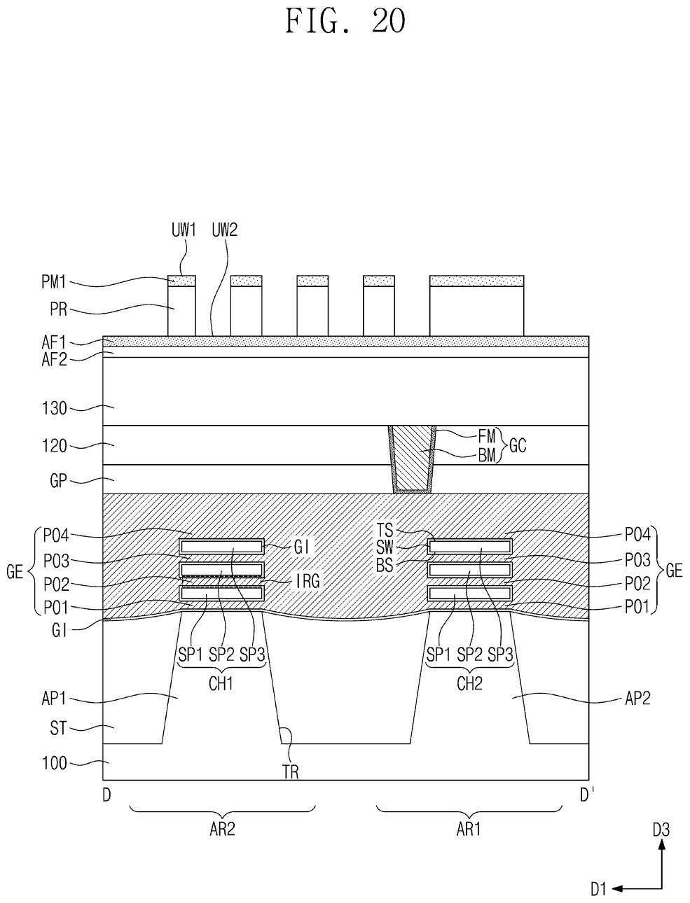

Referring to FIG. 19, a first polymer layer PMF1 may be formed on the photoresist patterns PR and the first anti-reflection pattern AF1. The first polymer layer PMF1 may be formed on the entire surface of the substrate 100. The first polymer layer PMF1 may cover an upper surface and sidewalls of the photoresist patterns PR. The first polymer layer PMF1 may cover an upper surface of the first anti-reflection pattern AF1 exposed by the photoresist patterns PR.

Referring to FIG. 20, the first polymer layer PMF1 may be etched to form a first polymer pattern PM1 on the upper surface of the photoresist patterns PR. A line width of the first polymer pattern PM1 may be substantially the same as the line width of the photoresist patterns PR. The first polymer pattern PM1 may include a first upper surface UW1. As the first polymer layer PMF1 is etched, a second upper surface UW2 of the first anti-reflection pattern may be exposed.

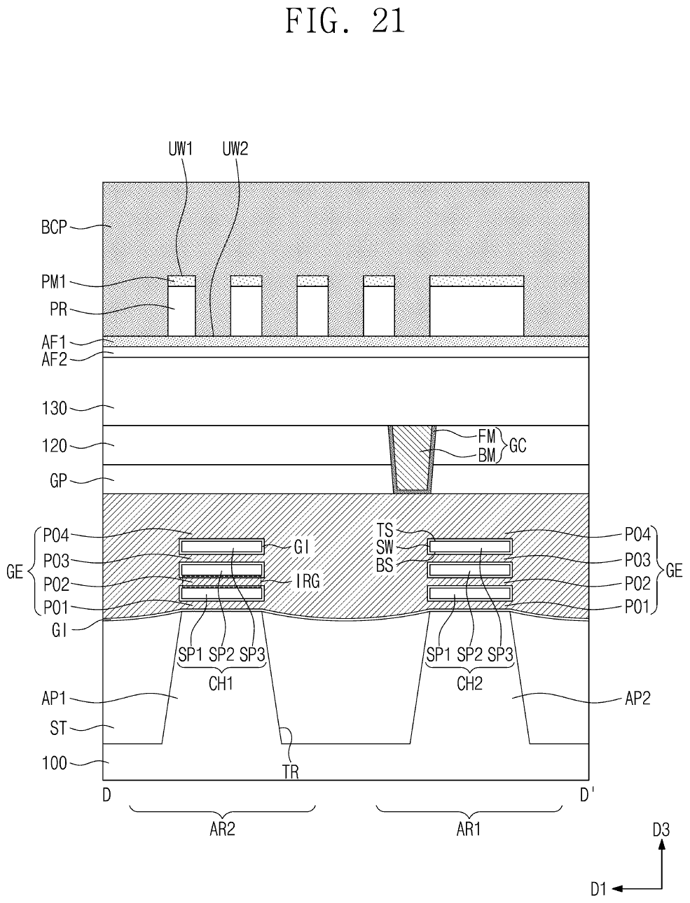

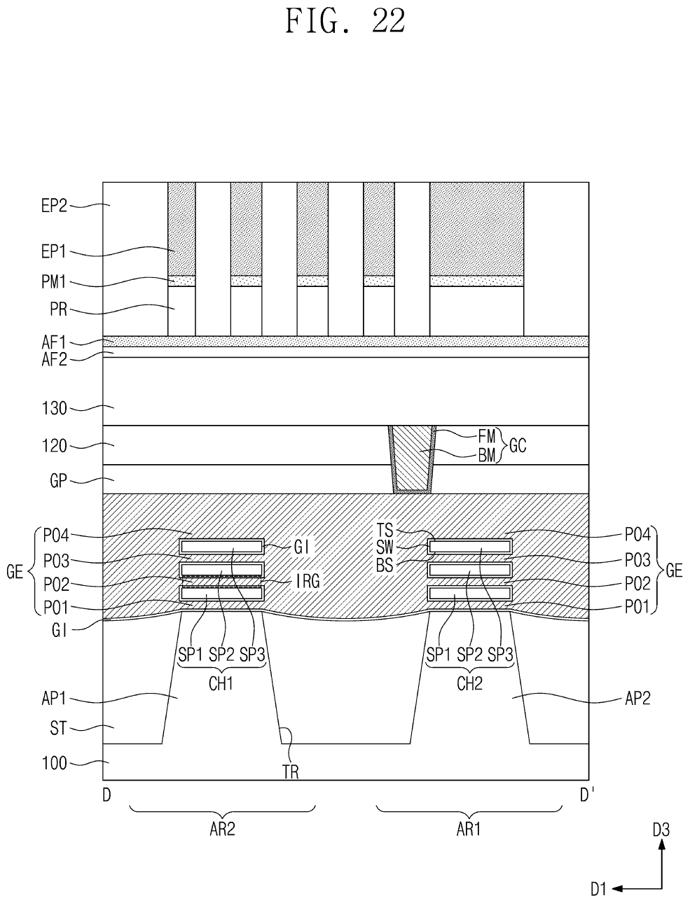

Referring to FIG. 21, a copolymer layer BCP may be formed on the entire surface of the substrate 100. In detail, the copolymer layer BCP may cover a first upper surface UW1, the second upper surface UW2, and the sidewalls of the photoresist patterns PR. The copolymer layer BCP may include different first polymers and second polymers.

Referring to FIG. 22, an annealing process may be performed on the copolymer layer BCP to separate the copolymer layer BCP into a first extended pattern EP1 and a second extended pattern EP2. The first extended pattern EP1 may be formed by aligning the first polymer in the vertical direction D3. The second extended pattern EP2 may be formed by aligning the second polymer in the vertical direction D3.

For example, the first polymer of the first polymer pattern PM1 may be non-polar, and the second polymer may be polar. Accordingly, during the annealing process, the first polymer of the copolymer layer BCP may be aligned on the first upper surface UW1 of the first polymer pattern PM1, and the second polymer of the copolymer layer BCP may be aligned on the second upper surface UW2. The first upper surface UW1 may be friendlier to the first polymer than to the second polymer, thereby causing the first polymer to align. The second upper surface UW2 may be friendlier to the second polymer than to the first polymer, thereby causing the second polymer to align.

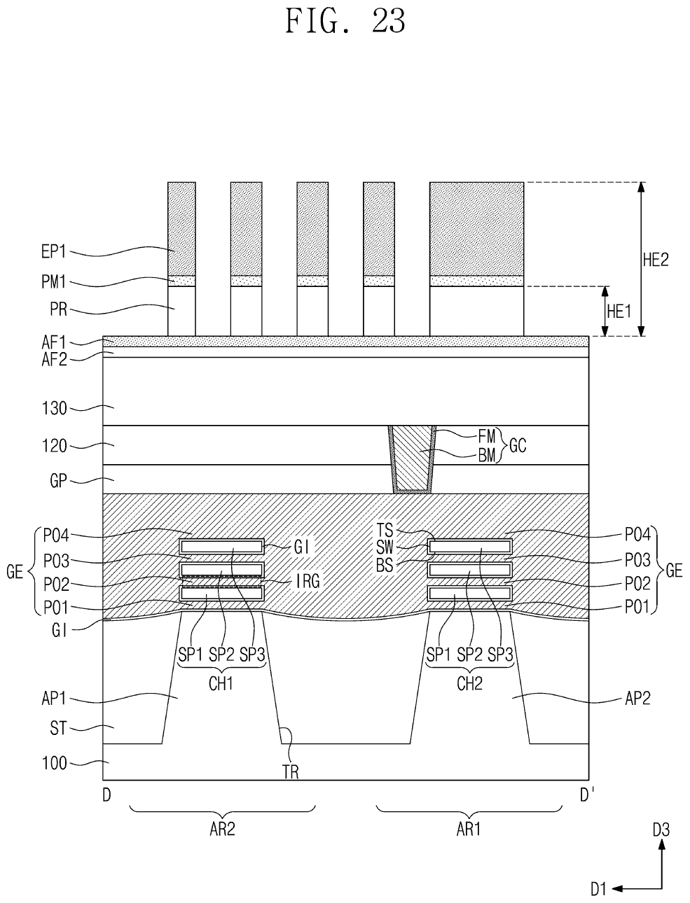

Referring to FIG. 23, the second extended pattern EP2 may be selectively removed by performing an etching process. The etching process may have different etch rates for the first polymer and the second polymer. The second extended pattern EP2 may be removed and the upper surface of the first anti-reflection pattern AF1 may be exposed again.

As forming the first polymer pattern PM1 and the first extended pattern EP1 on the photoresist pattern PR, a first height HE1 of the photoresist pattern PR extends to a second height HE2. The first height HE1 may be the vertical height of the photoresist pattern PR. The second height HE2 may be the sum of heights of the photoresist pattern, the first polymer pattern PM1, and the first extended pattern EP1.

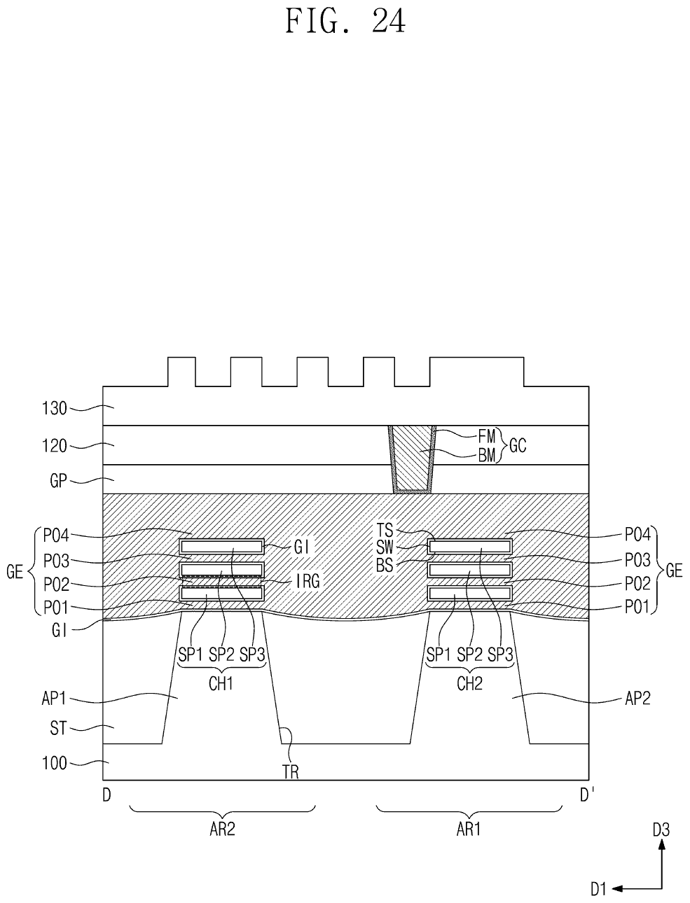

Referring to FIG. 24, the third interlayer insulating layer 130 may be patterned using the photoresist pattern PR and the first extended pattern EPI as an etch mask. Through the patterning process, an upper portion of the third interlayer insulating layer 130 may be etched. According to aspects of the inventive concept, as forming the first polymer pattern PM1 on the photoresist pattern PR, the first extended pattern EP1 may be accurately aligned on the photoresist pattern PR. Additionally, the DSA process may be performed on the photoresist pattern PR without a process of etching the photoresist pattern PR.

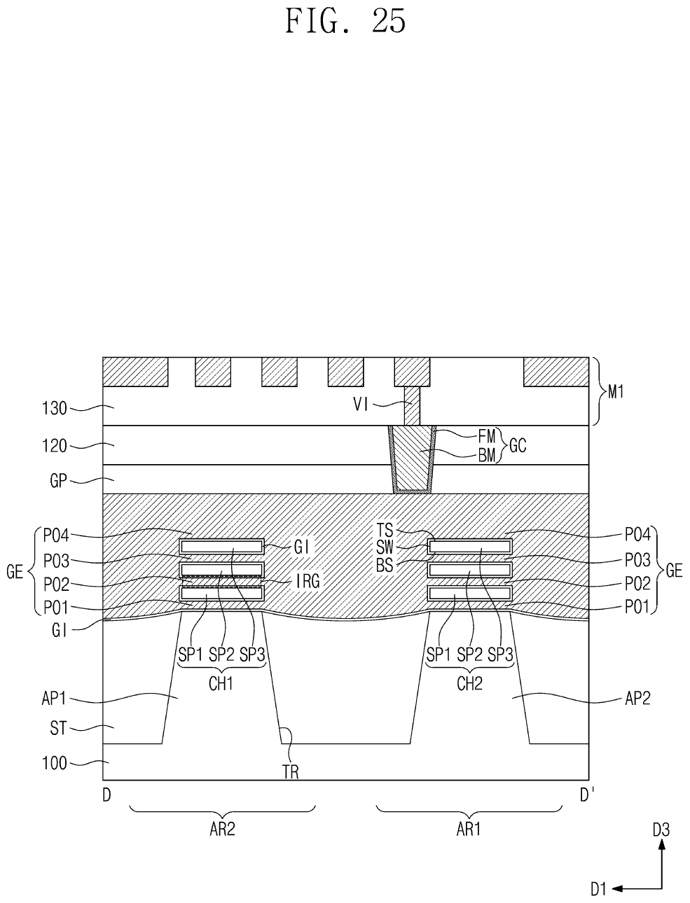

Referring to FIG. 25, the first metal layer M1 may be formed by filling the etched third interlayer insulating layer 130 with a metal material. For example, the metal material may include at least one selected from aluminum, copper, tungsten, molybdenum, ruthenium, and cobalt. A via VI vertically connected to the first metal layer M1 and the gate contact GC may be formed.

In the method of manufacturing the semiconductor device according to aspects of the inventive concept, before performing the directed self-assembly (DSA) process, the polymer pattern may be formed on the photoresist pattern. By forming the polymer pattern, the DSA process may be performed on the photoresist pattern without the need to etch the photoresist pattern. Additionally, the photoresist pattern may include metal oxide, allowing the finer pattern to be implemented on the wafer. As a result, the electrical characteristics and reliability of the semiconductor device according to the inventive concept may be improved.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the scope of the invention being indicated by the appended claims.

What is claimed is:

1. A method of manufacturing a semiconductor device, the method comprising:
forming a first anti-reflection pattern on a substrate;
forming a photoresist pattern on the first anti-reflection pattern;
forming a first polymer pattern on the photoresist pattern;
forming a copolymer layer on the first anti-reflection pattern and the first polymer pattern; and
performing an annealing process on the copolymer layer,
wherein the copolymer layer includes a first polymer and a second polymer different from the first polymer, and
wherein the first polymer pattern includes the first polymer.

2. The method of claim 1, wherein the photoresist pattern includes a metal oxide.

3. The method of claim 1, wherein the first polymer pattern includes a first upper surface,
wherein the forming of the first polymer pattern includes:
forming a first polymer layer on the first anti-reflection pattern and the photoresist pattern; and
etching the first polymer layer to expose a second upper surface of the first anti-reflection pattern.

4. The method of claim 3, wherein the annealing process includes:
aligning the first polymer in a vertical direction on the first polymer pattern to form a first extended pattern; and
aligning the second polymer in the vertical direction on the second upper surface to form a second extended pattern.

5. The method of claim 3, wherein the photoresist pattern is one of a plurality of photoresist patterns, and further comprising:
forming a second polymer layer on the first upper surface and the second upper surface; and
etching the second polymer layer to form a second polymer pattern between adjacent photoresist patterns,
wherein the second polymer pattern includes a third upper surface, and
wherein the third upper surface is polar.

6. The method of claim 5, wherein the second polymer pattern includes the second polymer.

7. The method of claim 1, wherein one of the first polymer and the second polymer is polar and the other is non-polar.

8. The method of claim 1, further comprising a second anti-reflection pattern between the substrate and the first anti-reflection pattern,
wherein the second anti-reflection pattern includes a spin-on carbon (SOC) layer or an amorphous carbon layer.

9. The method of claim 1, wherein the photoresist pattern is one of a plurality of photoresist patterns, and further comprising a first spacing, which is a spacing between adjacent photoresist patterns,
wherein each photoresist pattern has a first line width, and
wherein the sum of the first line width and the first spacing is 22 nm to 26 nm.

10. A method of manufacturing a semiconductor device, the method comprising:
forming an anti-reflection pattern and a photoresist layer sequentially stacked on a substrate;
irradiating the photoresist layer with extreme ultraviolet light to form a photoresist pattern;
forming a first polymer pattern on the photoresist pattern;
forming a copolymer layer covering a first material region on the first polymer pattern and a second material region on the anti-reflection pattern; and
performing an annealing process on the copolymer layer,
wherein one of the first material region and the second material region is polar and the other is non-polar.

11. The method of claim 10, wherein the photoresist pattern includes a metal oxide.

12. The method of claim 10, wherein the copolymer layer includes a first polymer and a second polymer different from each other, and
wherein the first polymer pattern includes the first polymer.

13. The method of claim 12, wherein irradiating the photoresist layer with extreme ultraviolet light to form a photoresist pattern forms a plurality of photoresist patterns, and further comprising forming a second polymer pattern between adjacent photoresist patterns of the plurality of photoresist patterns,
wherein the second polymer pattern includes the second polymer.

14. The method of claim 13, wherein the annealing process includes:
aligning the first polymer in a vertical direction on the first polymer pattern; and
aligning the second polymer in the vertical direction on the second polymer pattern.

15. The method of claim 12, wherein one of the first polymer and the second polymer is polar and the other is non-polar.

16. A method of manufacturing a semiconductor device, the method comprising:
forming transistors on a substrate; and
forming a first wiring layer on the transistor,
wherein the forming of the first wiring layer includes:
forming an interlayer insulating layer, a first anti-reflection pattern, and a photoresist pattern sequentially stacked on the transistor;
forming a first polymer pattern on the photoresist pattern;
forming a copolymer layer on the first anti-reflection pattern and the first polymer pattern, the copolymer layer including a first polymer and a second polymer different from each other; and
phase-separating the copolymer layer,
wherein the phase-separating of the copolymer layer includes aligning the first polymer in a vertical direction on the first polymer pattern.

17. The method of claim 16, wherein the first polymer pattern includes the first polymer.

18. The method of claim 16, wherein one of the first polymer and the second polymer is polar and the other is non-polar.

19. The method of claim 16, wherein the photoresist pattern is one of a plurality of photoresist patterns and further comprising forming a second polymer pattern between the photoresist patterns,
wherein the second polymer pattern includes the second polymer.

20. The method of claim 16, wherein the photoresist pattern is one of a plurality of photoresist patterns and further comprising a first spacing, which is a spacing between adjacent photoresist patterns,
wherein each photoresist pattern has a first line width, and
wherein the sum of the first line width and the first spacing is 22 nm to 26 nm.
